(19) United States
(12) Patent Application Publication
(10) Pub. No.: US 2025/0149405 A1
(43) Pub. Date: May 8, 2025

(54) SEMICONDUCTOR DEVICE, ELECTRIC POWER CONVERSION UNIT AND METHOD FOR MANUFACTURING SEMICONDUCTOR DEVICE

(71) Applicant: ROHM CO., LTD., Kyoto-shi (JP)

(72) Inventor: Kazunori FUJI, Kyoto-shi (JP)

(21) Appl. No.: 19/020,477

(22) Filed: Jan. 14, 2025

Related U.S. Application Data
(63) Continuation of application No. PCT/JP2023/023825, filed on Jun. 27, 2023.

(30) Foreign Application Priority Data
Jul. 25, 2022 (JP) 2022-118313

(51) Int. Cl. H01L 23/433; H01L 21/48; H02M 7/00

(52) U.S. Cl. CPC H01L 23/4334; H01L 21/4882; H02M 7/003

(57) ABSTRACT

A semiconductor device includes a first semiconductor element, a second semiconductor element, a support substrate and a sealing resin, and further includes a heat dissipation member disposed on the reverse surface. The heat dissipation member includes a plurality of first protruding elements each including a first base portion, a second base portion, a first standing portion, a second standing portion, and a first end portion. The plurality of first protruding elements are arranged in a matrix along a plane containing the first direction and the second direction.

### TECHNICAL FIELD

The present disclosure relates to a semiconductor device, an electric power conversion unit, and a method for manufacturing the semiconductor device.

### BACKGROUND ART

Semiconductor devices with power switching elements such as MOSFETS (Metal Oxide Semiconductor Field Effect Transistors) or IGBTs (Insulated Gate Bipolar Transistors) are conventionally known. Such semiconductor devices are used in a variety of electronic equipment, including industrial equipment, home appliances, information terminals, and automotive equipment. A conventional semiconductor device (power module) is disclosed in Patent Document 1. The semiconductor device disclosed in Patent Document 1 includes a semiconductor element and a support substrate (ceramic substrate). The semiconductor element is, for example, an IGBT made of Si (silicon). The support substrate supports the semiconductor element. The support substrate includes an insulating base and a conductive layer provided on each side of the base. The base is made of, for example, a ceramic material. The conductive layers are made of Cu (copper), for example. The semiconductor element is bonded to one of the conductive layers. The semiconductor element may be covered with sealing resin.

### BRIEF DESCRIPTION OF THE DRAWINGS

FIG. 1 is a perspective view of a semiconductor device according to a first embodiment of the present disclosure.

FIG. 2 is a partial perspective view of the semiconductor device according to the first embodiment of the present disclosure.

FIG. 3 is a partial perspective view of the semiconductor device according to the first embodiment of the present disclosure.

FIG. 4 is a plan view of the semiconductor device according to the first embodiment of the present disclosure.

FIG. 5 is a partial plan view of the semiconductor device according to the first embodiment of the present disclosure.

FIG. 6 is a partial side view of the semiconductor device according to the first embodiment of the present disclosure.

FIG. 7 is a partial enlarged plan view of the semiconductor device according to the first embodiment of the present disclosure.

FIG. 8 is a partial plan view of the semiconductor device according to the first embodiment of the present disclosure.

FIG. 9 is a partial plan view of the semiconductor device according to the first embodiment of the present disclosure.

FIG. 10 is a side view of the semiconductor device according to the first embodiment of the present disclosure.

FIG. 11 is a bottom view of the semiconductor device according to the first embodiment of the present disclosure.

FIG. 12 is a sectional view taken along line XII-XII in FIG. 5.

FIG. 13 is a sectional view taken along line XIII-XIII in FIG. 5.

FIG. 14 is a partial enlarged sectional view of the semiconductor device according to the first embodiment of the present disclosure.

FIG. 15 is a partial enlarged sectional view of the semiconductor device according to the first embodiment of the present disclosure.

FIG. 16 is a sectional view taken along line XVI-XVI in FIG. 5.

FIG. 17 is a sectional view taken along line XVII-XVII in FIG. 5.

FIG. 18 is a sectional view taken along line XVIII-XVIII in FIG. 5.

FIG. 19 is a sectional view taken along line XIX-XIX in FIG. 5.

FIG. 20 is a sectional view taken along line XX-XX in FIG. 5.

FIG. 21 is a partial perspective view of the heat dissipation member of the semiconductor device according to the first embodiment of the present disclosure.

FIG. 22 is a partial plan view of the heat dissipation member of the semiconductor device according to the first embodiment of the present disclosure.

FIG. 23 is a partial sectional view taken along line XXIII-XXIII in FIG. 22.

FIG. 24 is a partial sectional view taken along line XXIV-XXIV in FIG. 22.

FIG. 25 is a partial sectional view taken along line XXV-XXV in FIG. 22.

FIG. 26 is a partial sectional view taken along line XXVI-XXVI in FIG. 22.

FIG. 27 shows the semiconductor device according to the first embodiment of the present disclosure, where (a) is a partial front view of the heat dissipation member, (b) is a partial sectional view of the metal plate material, and (c) is a partial plan view of the metal plate material.

FIG. 28 shows the heat dissipation member of the semiconductor device according to the first embodiment of the present disclosure, where (a) is a partial perspective view of the heat dissipation member, and (b) to (d) are perspective views showing bond planes.

FIG. 29 is a sectional view of an electric power conversion unit according to the first embodiment of the present disclosure.

FIG. 30 is a sectional view of the electric power conversion unit according to the first embodiment of the present disclosure.

FIG. 31 is a partial perspective view of the heat dissipation member of the semiconductor device according to a second embodiment of the present disclosure.

FIG. 32 is a partial plan view of the heat dissipation member of the semiconductor device according to the second embodiment of the present disclosure.

FIG. 33 is a partial sectional view taken along line XXXIII-XXXIII in FIG. 32.

FIG. 34 is a partial sectional view taken along line XXXIV-XXXIV in FIG. 32.

FIG. 35 is a partial sectional view taken along line XXXV-XXXV in FIG. 32.

FIG. 36 is a partial sectional view taken along line XXXVI-XXXVI in FIG. 32.

FIG. 37 is a partial perspective view of the heat dissipation member of the semiconductor device according to a third embodiment of the present disclosure.

FIG. 38 is a partial plan view of the heat dissipation member of the semiconductor device according to the third embodiment of the present disclosure.

FIG. 39 is a partial sectional view taken along line XXXIX-XXXIX in FIG. 38.

FIG. 40 is a partial sectional view taken along line XL-XL in FIG. 38.

FIG. 41 is a partial sectional view taken along line XLI-XLI in FIG. 38.

FIG. 42 is a partial sectional view taken along line XLII-XLII in FIG. 38.

FIG. 43 is a partial perspective view of the heat dissipation member of the semiconductor device according to a third embodiment of the present disclosure.

FIG. 44 is a partial plan view of the heat dissipation member of the semiconductor device according to the third embodiment of the present disclosure.

FIG. 45 is a partial sectional view taken along line XLV-XLV in FIG. 44.

FIG. 46 is a partial sectional view taken along line XLVI-XLVI in FIG. 44.

FIG. 47 is a partial sectional view taken along line XLVII-XLVII in FIG. 44.

FIG. 48 is a partial sectional view taken along line XLVIII-XLVIII in FIG. 44.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Furthermore, in the description of the present disclosure, the expression “A surface A faces (a first side or a second side) in a direction B” is not limited to the situation where the angle of the surface A to the direction B is 90° and includes the situation where the surface A is inclined with respect to the direction B.

### FIRST EMBODIMENT

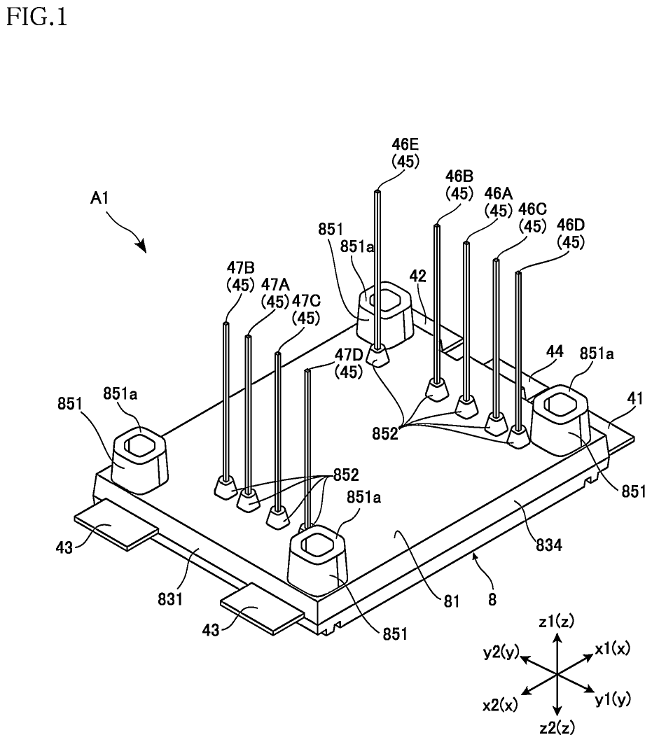

FIGS. 1 to 30 show a semiconductor device and an electric power conversion unit according to a first embodiment of the present disclosure. The semiconductor device A1 of the present embodiment includes a plurality of first semiconductor elements 10A, a plurality of second semiconductor elements 10B, a heat dissipation member 2, a support substrate 3, a first terminal 41, a second terminal 42, a plurality of third terminals 43, a fourth terminal 44, a plurality of control terminals 45, a control terminal support 48, a first conductive member 5, a second conductive member 6, and a sealing resin 8.

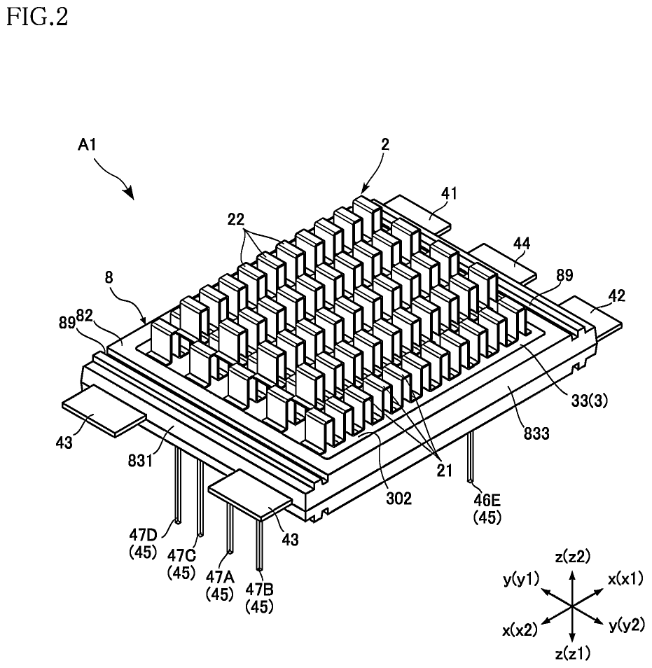

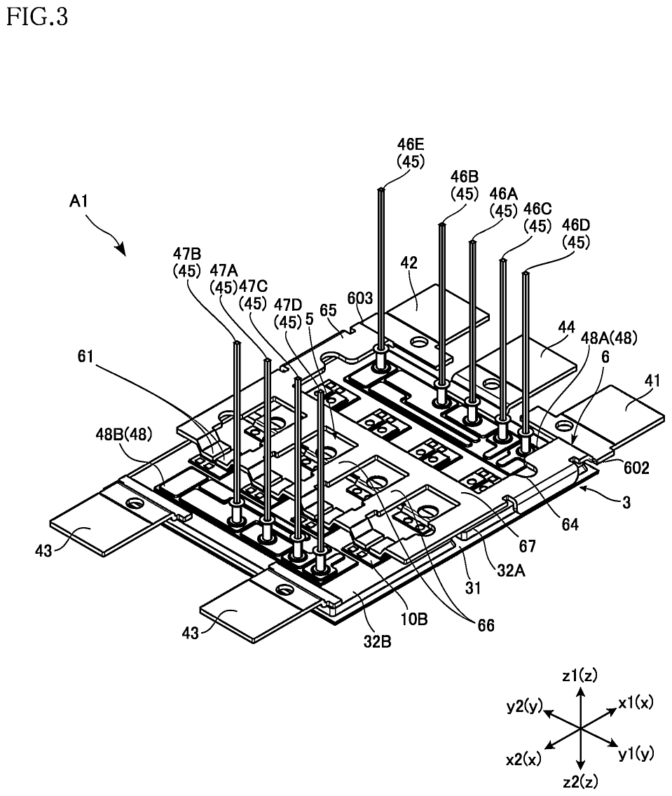

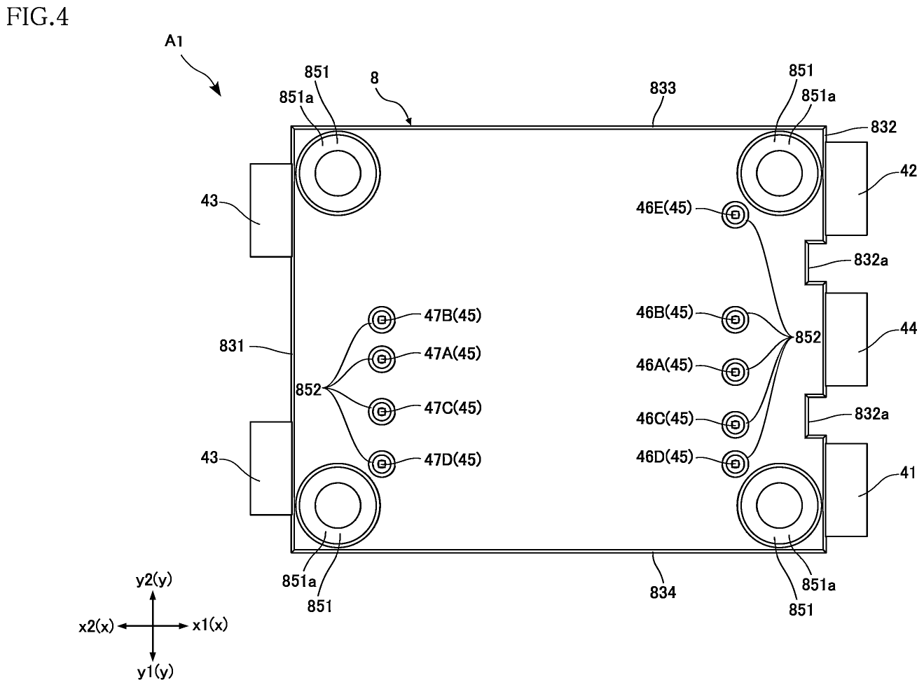

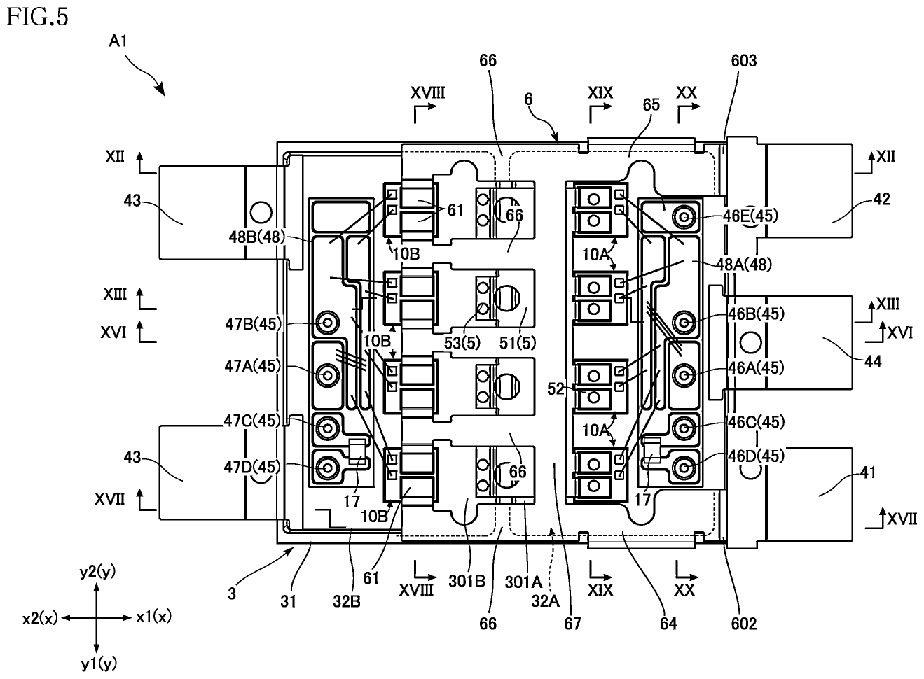

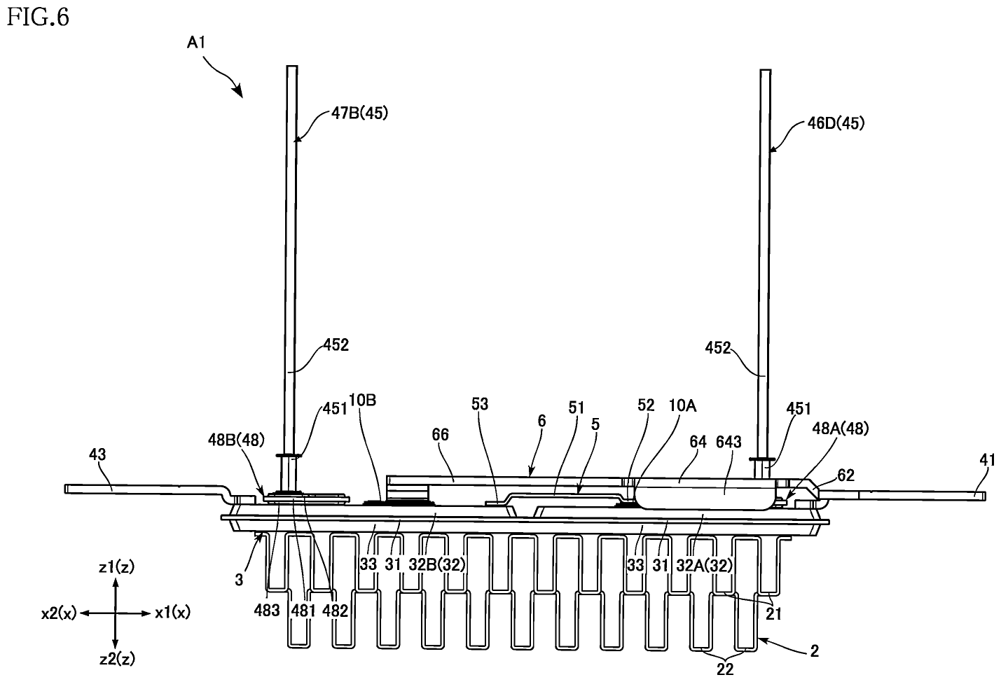

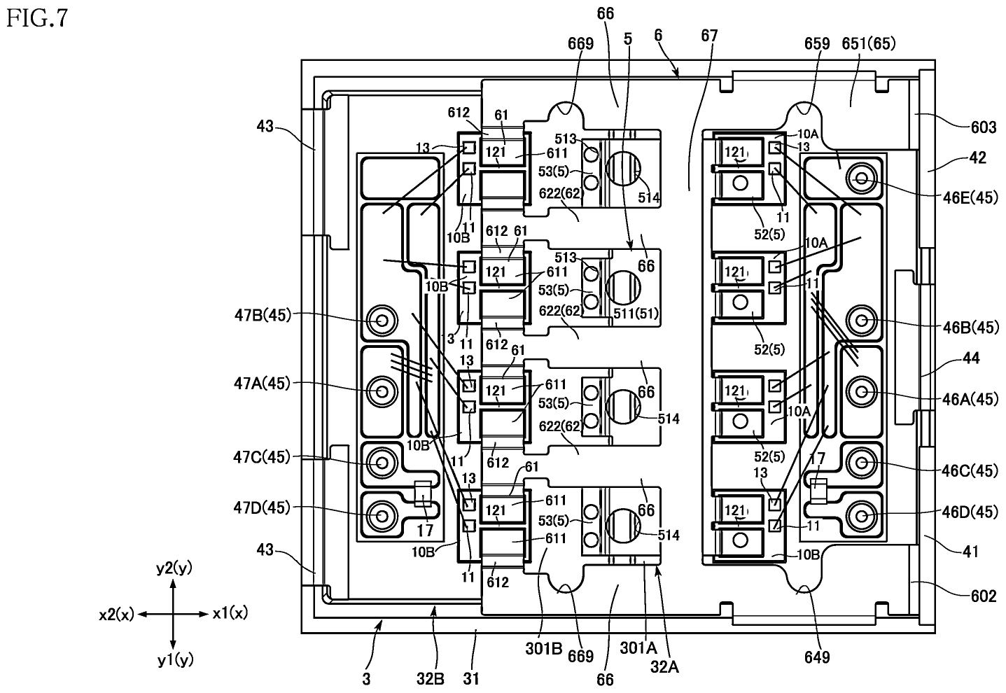

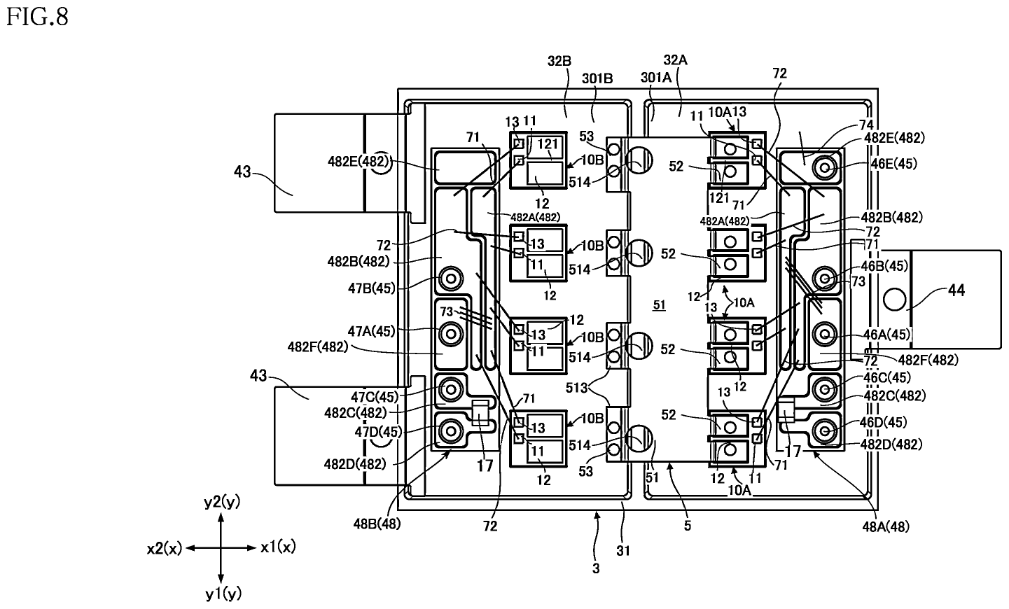

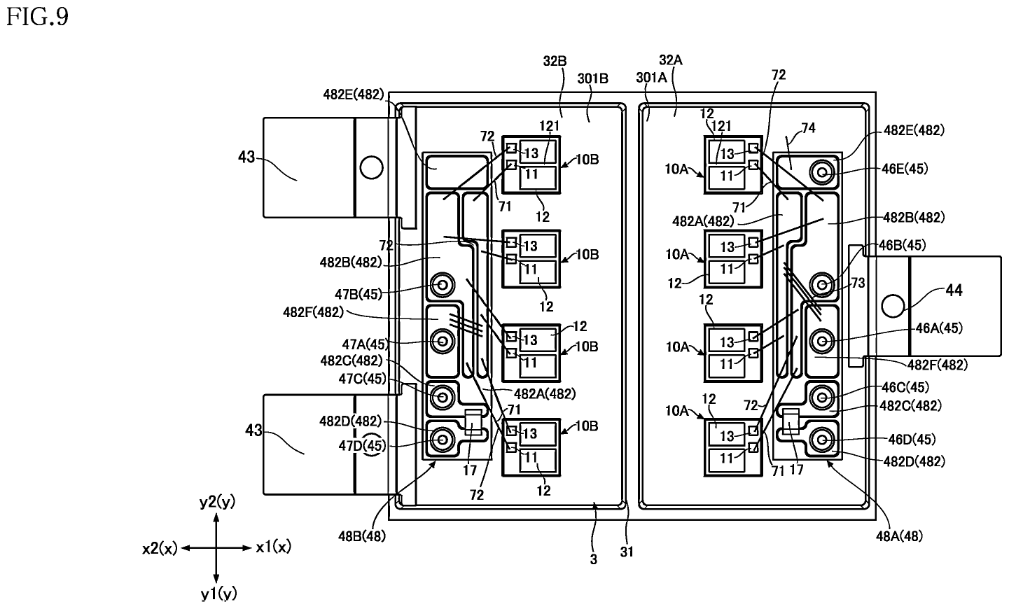

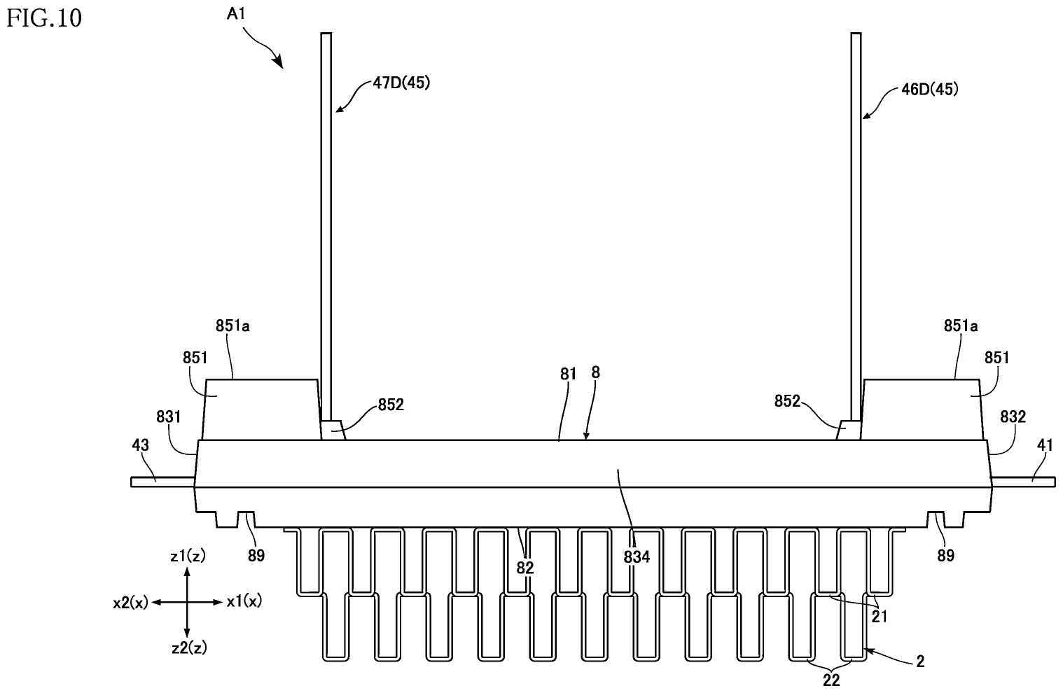

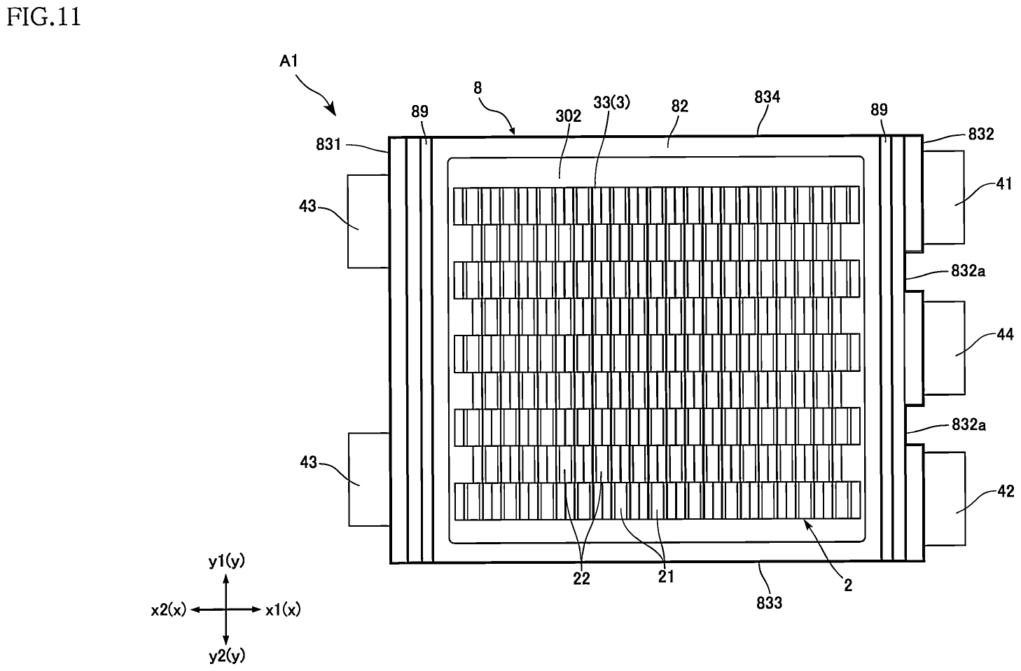

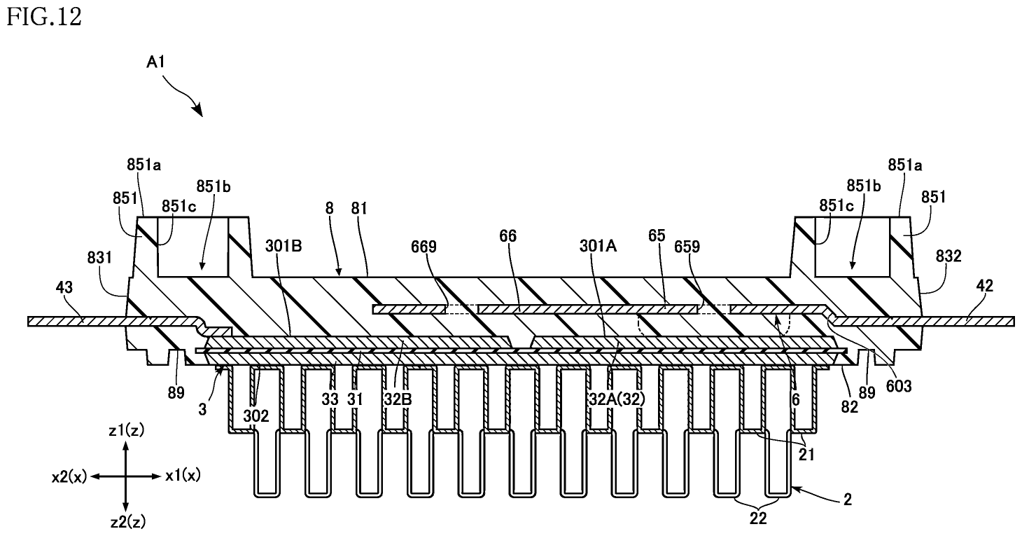

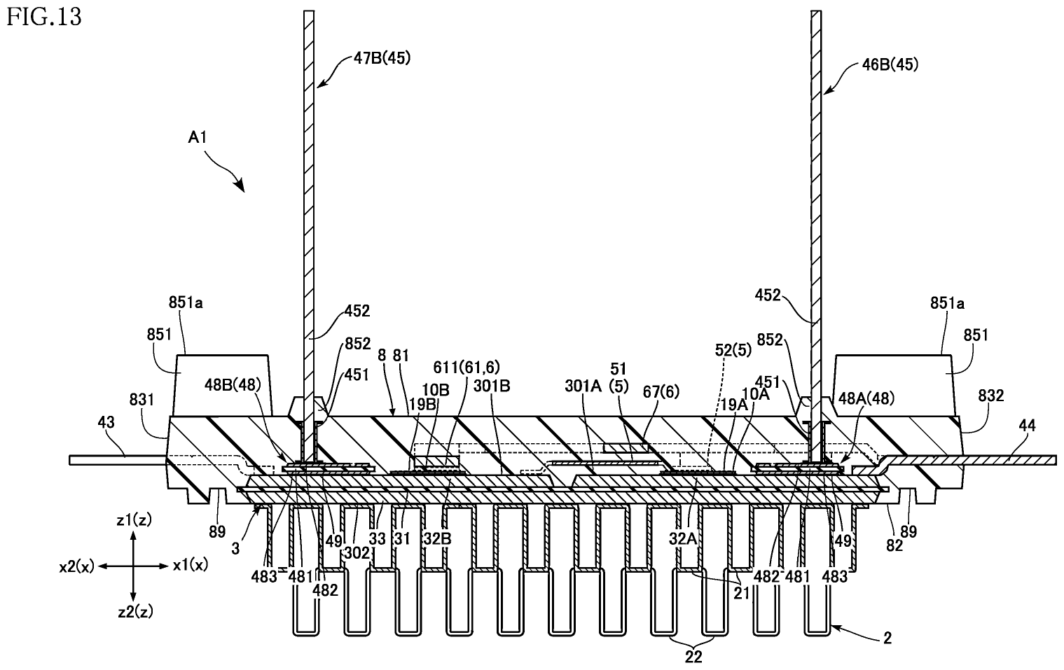

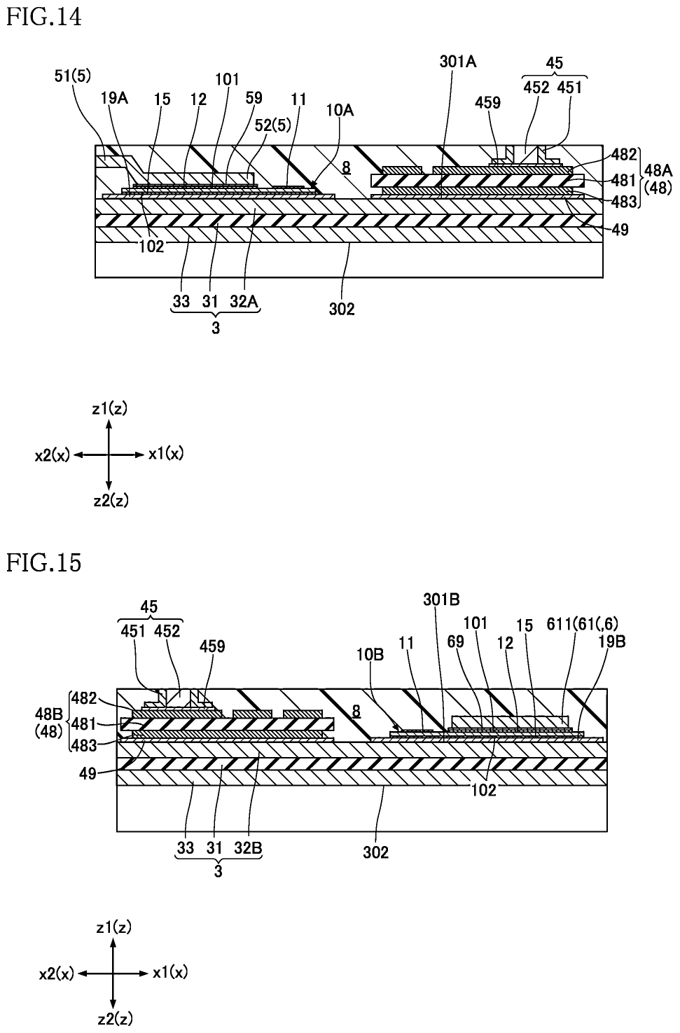

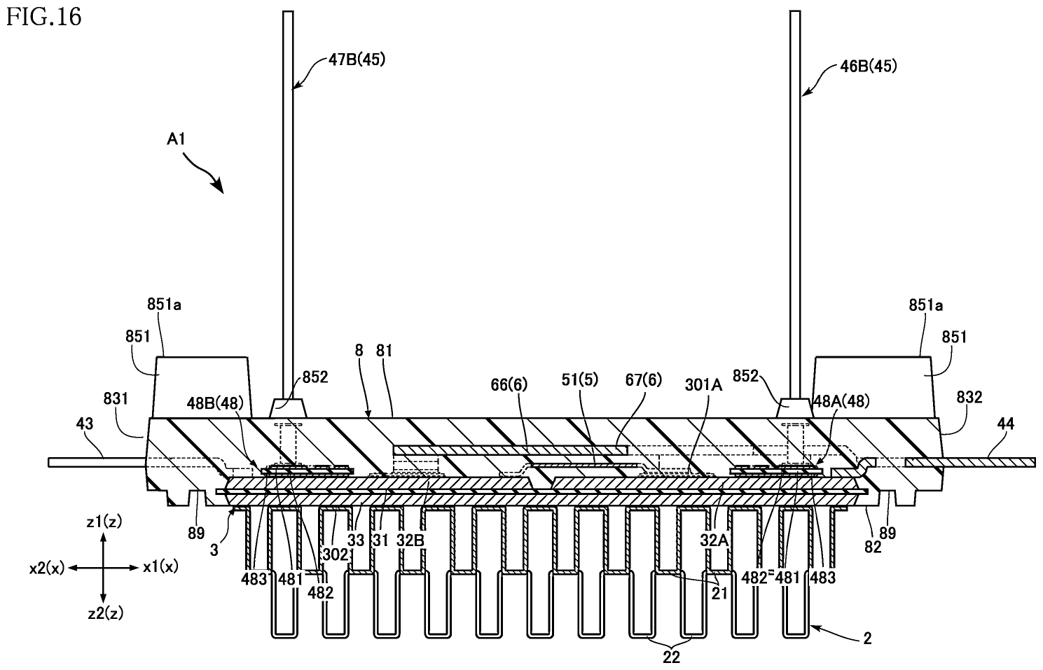

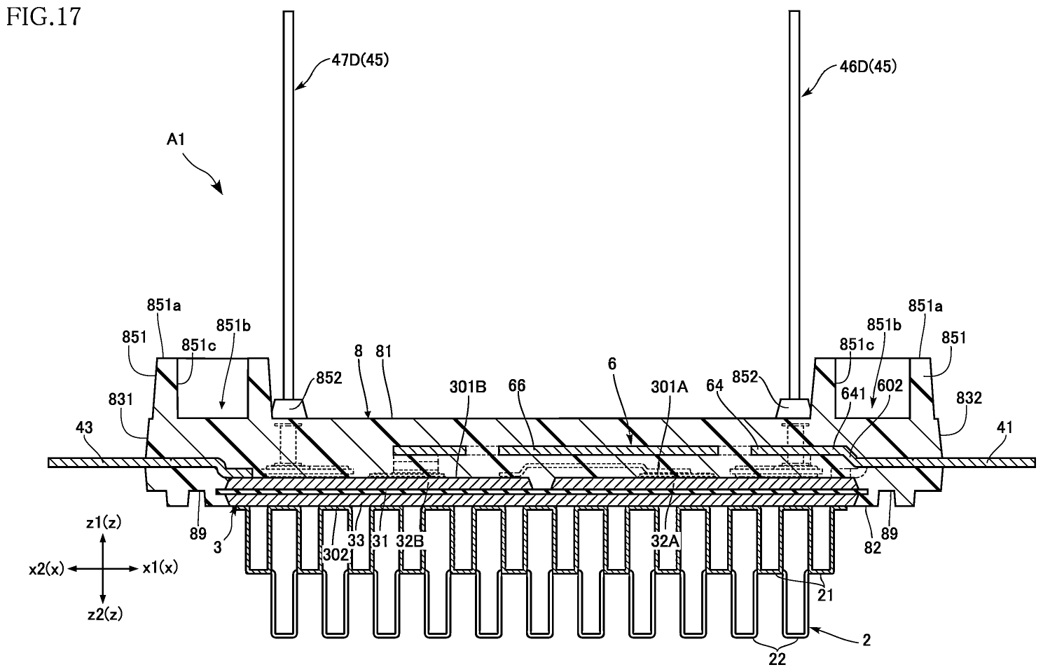

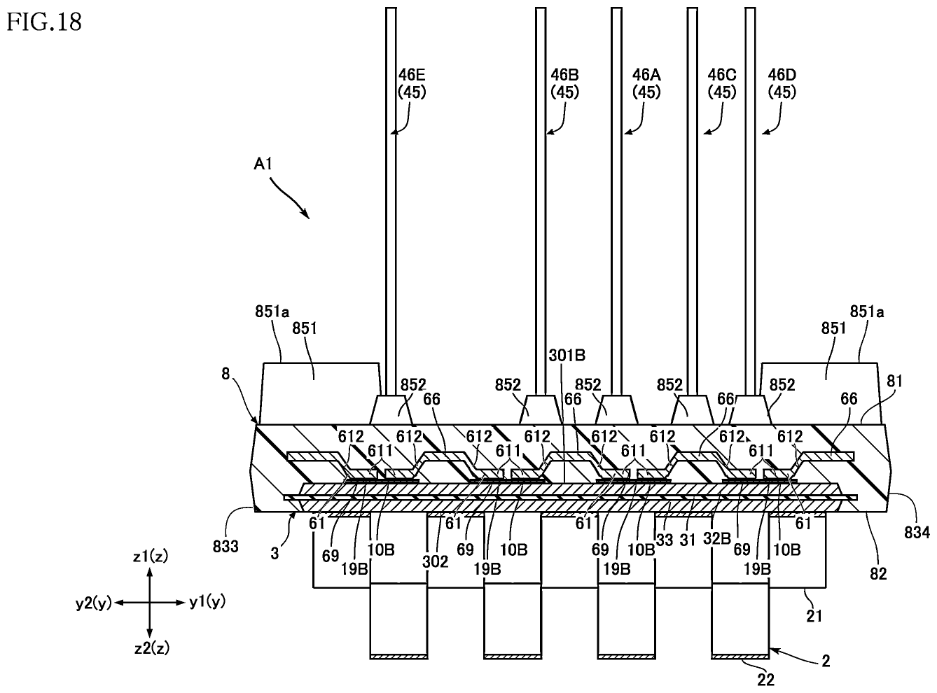

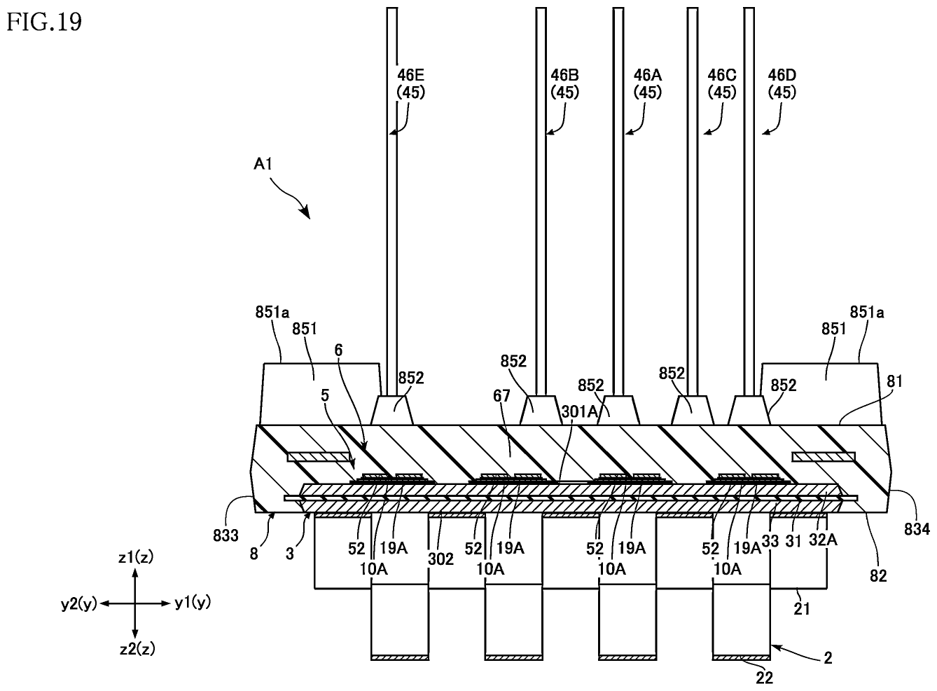

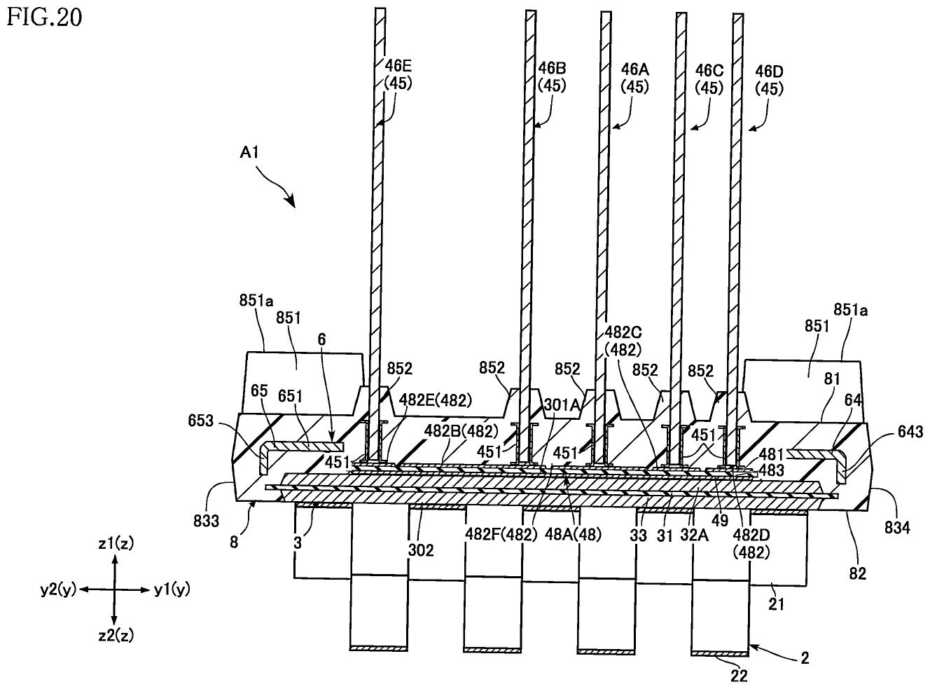

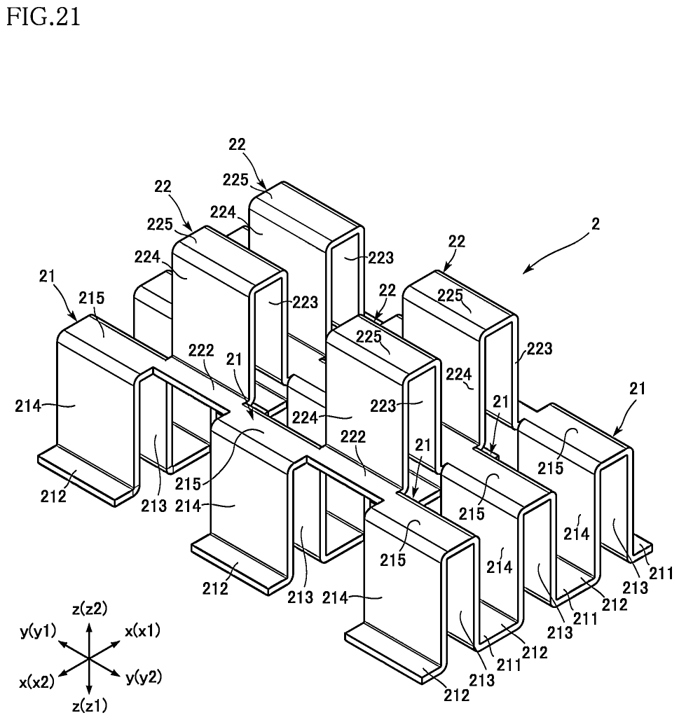

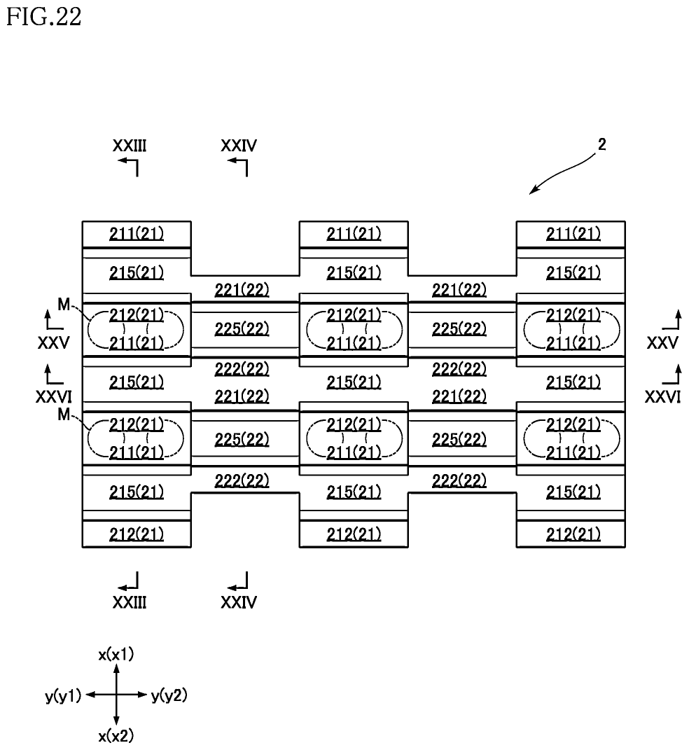

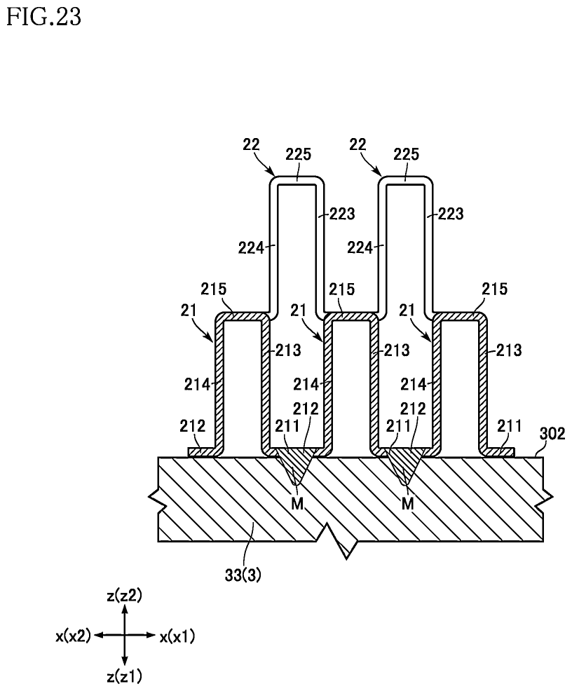

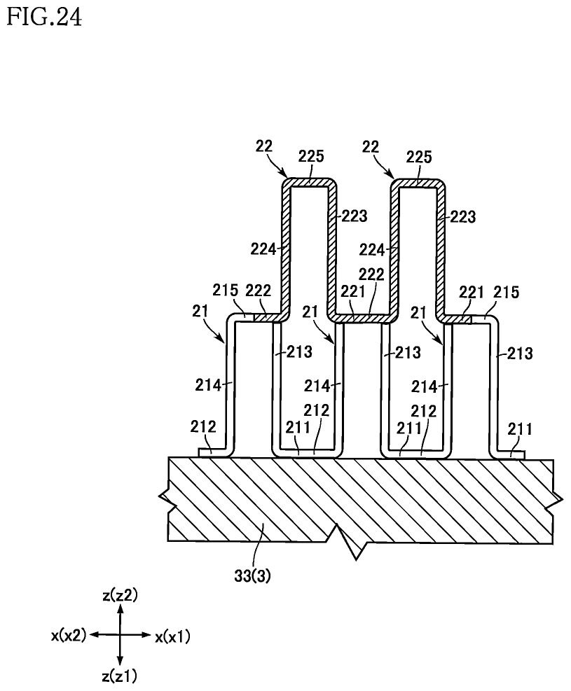

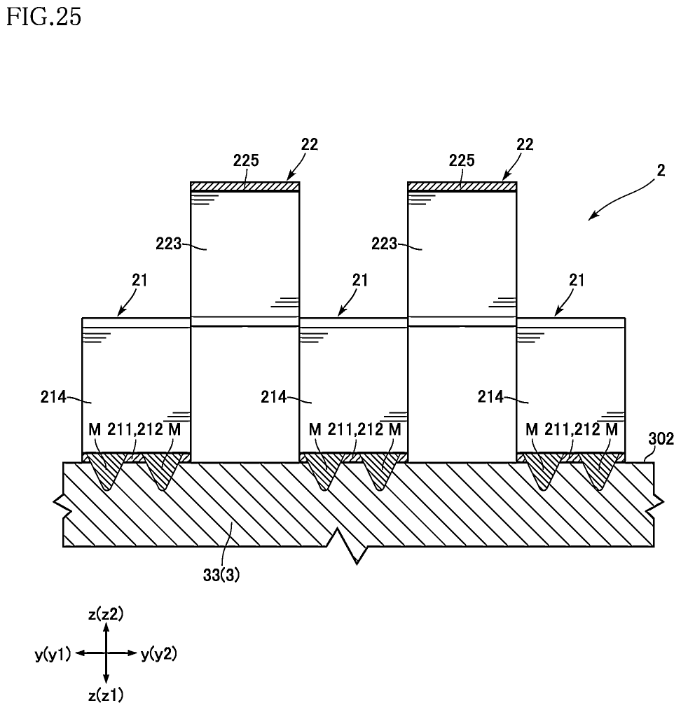

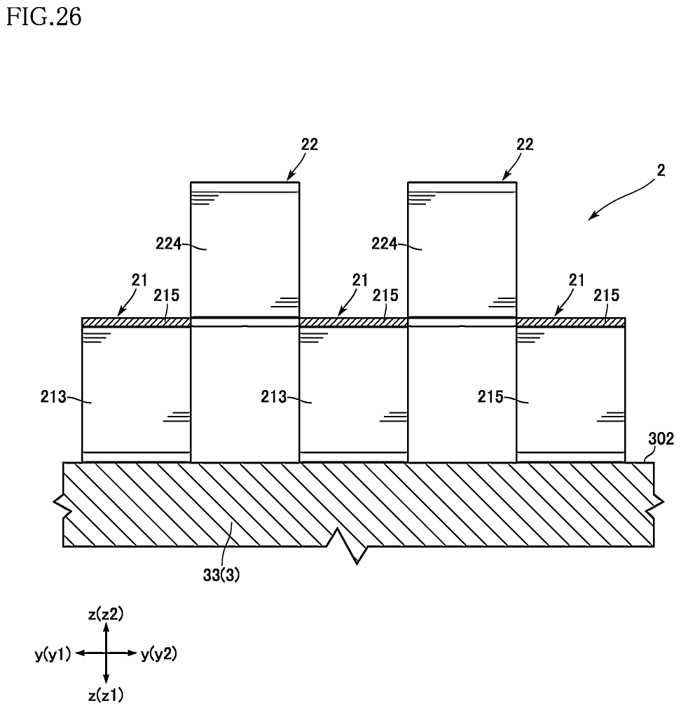

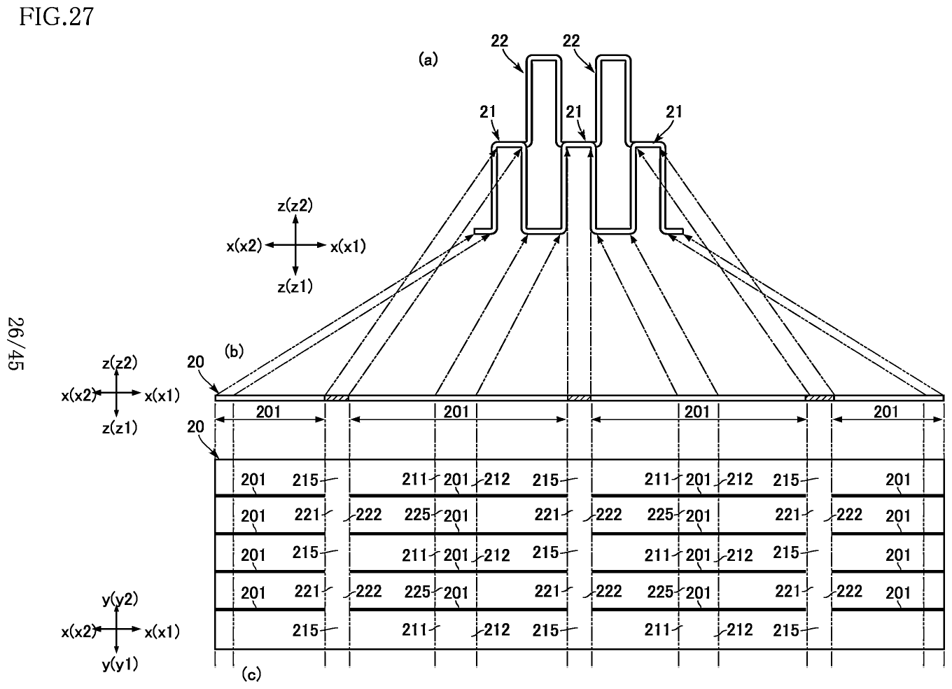

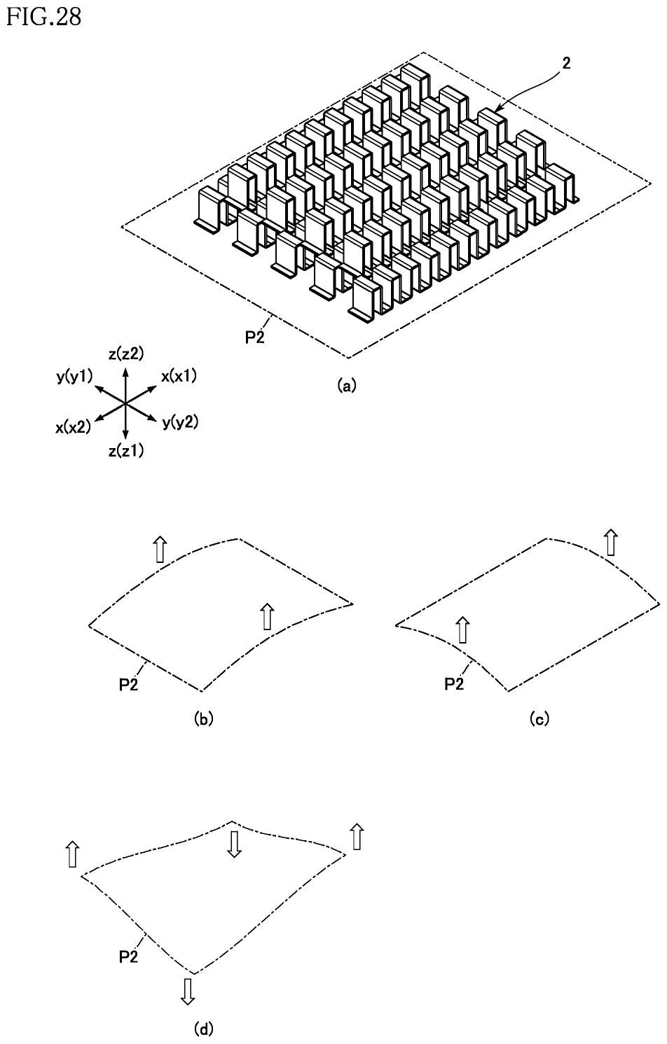

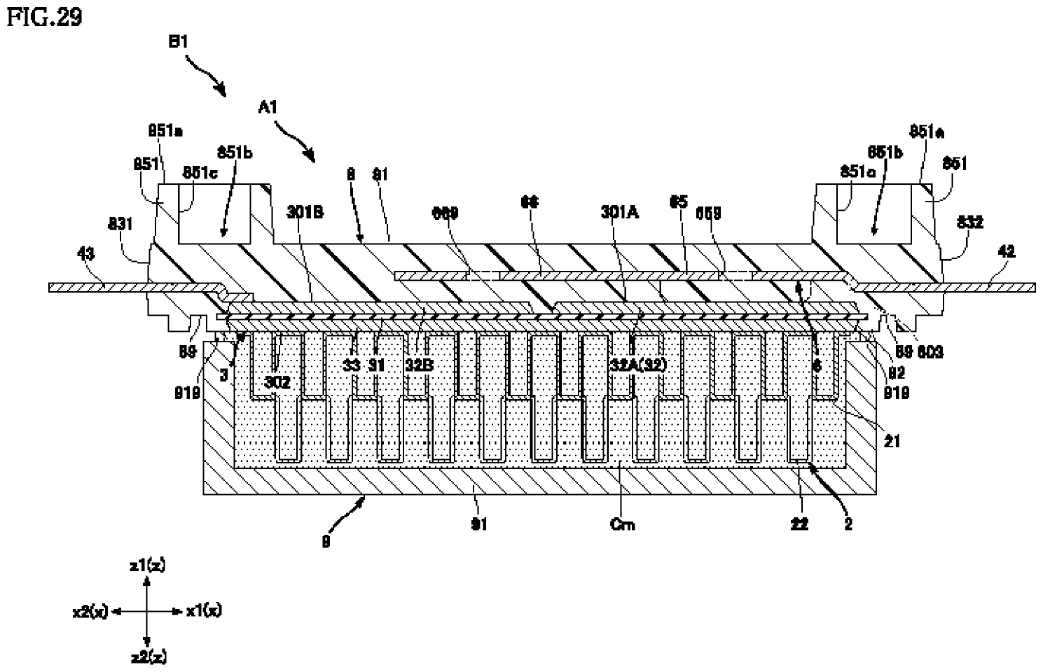

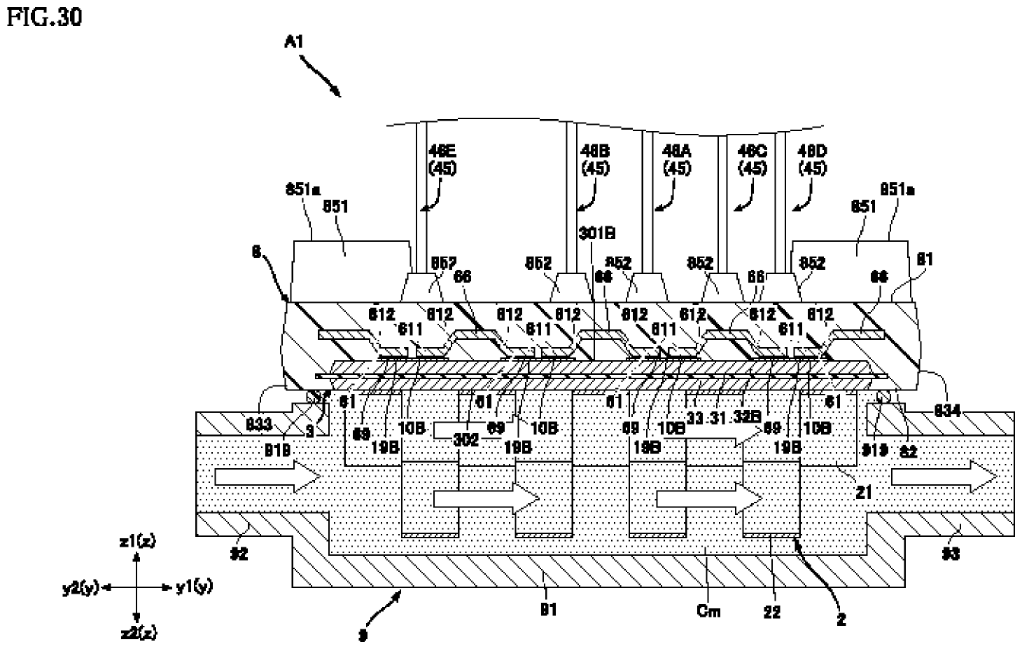

FIGS. 1 and 2 are perspective views showing the semiconductor device A1. FIG. 3 is a partial perspective view of the semiconductor device A1. FIG. 4 is a plan view of the semiconductor device A1. FIG. 5 is a partial plan view of the semiconductor device A1. FIG. 6 is a partial side view of the semiconductor device A1. FIG. 7 is a partial enlarged plan view of the semiconductor device A1. FIGS. 8 and 9 are partial plan views of the semiconductor device A1. FIG. 10 is a side view of the semiconductor device A1. FIG. 11 is a bottom view of the semiconductor device A1. FIG. 12 is a sectional view taken along line XII-XII in FIG. 5. FIG. 13 is a sectional view taken along line XIII-XIII in FIG. 5. FIGS. 14 and 15 are partial enlarged sectional views of the semiconductor device A1. FIG. 16 is a sectional view taken along line XVI-XVI in FIG. 5. FIG. 17 is a sectional view taken along line XVII-XVII in FIG. 5. FIG. 18 is a sectional view taken along line XVIII-XVIII in FIG. 5. FIG. 19 is a sectional view taken along line XIX-XIX in FIG. 5. FIG. 20 is a sectional view taken along line XX-XX in FIG. 5. FIG. 21 is a partial perspective view of the heat dissipation member 2 of the semiconductor device A1. FIG. 22 is a partial plan view of the heat dissipation member 2 of the semiconductor device A1. FIG. 23 is a partial sectional view taken along line XXIII-XXIII in FIG. 22. FIG. 24 is a partial sectional view taken along line XXIV-XXIV in FIG. 22. FIG. 25 is a partial sectional view taken along line XXV-XXV in FIG. 22. FIG. 26 is a partial sectional view taken along line XXVI-XXVI in FIG. 22. In FIG. 27, (a) is a partial front view of the heat dissipation member 2 of the semiconductor device A1, (b) is a partial sectional view of the metal plate material, and (c) is a partial plan view of the metal plate material. In FIG. 28, (a) is a partial perspective view of the heat dissipation member, and (b) to (d) are perspective views showing bond planes. FIGS. 29 and 30 are sectional views showing the electric power conversion unit B1.

In these figures, one side in the first direction x is referred to as the x1 side in the first direction x, and the other side in the first direction x is referred to as the x2 side in the first direction x. Also, one side in the second direction y is referred to as the y1 side in the second direction y, and the other side in the second direction y is referred to as the y2 side in the second direction y. Also, one side in the thickness direction z is referred to as the z1 side in the thickness direction z, and the other side in the thickness direction z is referred to as the z2 side in the thickness direction z.

First semiconductor element 10A, Second semiconductor element 10B:
Each of the first semiconductor elements 10A and the second semiconductor elements 10B is an electronic component as a core for the function of the semiconductor device A1. The constituent material of the first semiconductor elements 10A and the second semiconductor elements 10B is, for example, a semiconductor material mainly composed of SiC (silicon carbide). The semiconductor material is not limited to SiC, and may be, for example, Si (silicon), GaN (gallium nitride) or C (diamond). Each of the first semiconductor elements 10A and the second semiconductor elements 10B is a power semiconductor chip having a switching function, such as a MOSFET (Metal Oxide Semiconductor Field Effect Transistor). The first semiconductor elements 10A and the second semiconductor elements 10B are MOSFETs in the present embodiment, but are not limited to these and may be other IGBTs (Insulated Gate Bipolar transistors, such as Transistors). The first semiconductor elements 10A and the second semiconductor elements 10B are all identical with each other. Each of the first semiconductor elements 10A and the second semiconductor elements 10B is, for example, an n-channel MOSFET, but may be a p-channel MOSFET.

As shown in FIGS. 14 and 15, each of the first semiconductor elements 10A and the second semiconductor elements 10B has an element obverse surface 101 and an element reverse surface 102. In each of the first semiconductor elements 10A and the second semiconductor elements 10B, the element obverse surface 101 and the element reverse surface 102 are spaced apart from each other in the thickness direction z. The element obverse surface 101 faces the z1 side in the thickness direction z, and the element reverse surface 102 faces the z2 side in the thickness direction z.

In the present embodiment, the semiconductor device A1 includes four first semiconductor elements 10A and four second semiconductor elements 10B. However, the number of first semiconductor elements 10A and the number of second semiconductor elements 10B are not limited to this configuration, and may be changed as appropriate in accordance with the performance required of the semiconductor device A1. In the example shown in FIGS. 8 and 9, four each of the first semiconductor elements 10A and the second semiconductor elements 10B are provided. The number of first semiconductor elements 10A and the number of second semiconductor elements 10B may be two, three, or five or more. The number of first semiconductor elements 10A and the number of second semiconductor elements 10B may be the same or may be different. The number of first semiconductor elements 10A and the number of second semiconductor elements 10B are determined based on the current capacity of the semiconductor device A1.

The semiconductor device A1 may be configured as a half-bridge type switching circuit. In this case, the first semiconductor elements 10A constitute the upper arm circuit of the semiconductor device A1, and the second semiconductor elements 10B constitute the lower arm circuit. In the upper arm circuit, the first semiconductor elements 10A are connected in parallel with each other. In the lower arm circuit, the second semiconductor elements 10B are connected in parallel with each other. Each first semiconductor element 10A and a relevant second semiconductor element 10B are connected in series to form a bridge layer.

As shown in FIGS. 8, 9, and 19, each of the first semiconductor elements 10A is mounted on the first conductive portion 32A of the support substrate 3, described later. In the example shown in FIGS. 8 and 9, the first semiconductor elements 10A may be aligned in the second direction y and are spaced apart from each other. Each of the first semiconductor elements 10A is conductively bonded to the first conductive portion 32A via a first conductive bonding material 19A. With the first semiconductor elements 10A bonded to the first conductive portion 32A, the element reverse surfaces 102 face the first conductive portion 32A. Unlike the present embodiment, the first semiconductor elements 10A may be mounted on a metal member different from a part of a DBC substrate or the like. In such a case, the metal member corresponds to the first conductive portion of the present disclosure. The metal member may be supported on, for example, the first conductive portion 32A.

As shown in FIGS. 8, 9, and 18, each of the second semiconductor elements 10B is mounted on the second conductive portion 32B of the support substrate 3, described later. In the example shown in FIGS. 8 and 9, the second semiconductor elements 10B may be aligned in the second direction y and are spaced apart from each other. Each of the second semiconductor elements 10B is conductively bonded to the second conductive portion 32B via a second conductive bonding material 19B. With the second semiconductor elements 10B bonded to the second conductive portion 32B, the element reverse surfaces 102 face the second conductive portion 32B. As understood from FIG. 9, the first semiconductor elements 10A and the second semiconductor elements 10B overlap with each other as viewed in the first direction x. However, the first semiconductor elements and the second semiconductor elements may not overlap with each other. Unlike the present embodiment, the second semiconductor elements 10B may be mounted on a metal member different from a part of a DBC substrate or the like. In such a case, the metal member corresponds to the second conductive portion of the present disclosure. The metal member may be supported on, for example, the second conductive portion 32B.

Each of the first semiconductor elements 10A and the second semiconductor elements 10B has a first obverse-surface electrode 11, a second obverse-surface electrode 12, a third obverse-surface electrode 13, and a reverse-surface electrode 15. The configurations of the first obverse-surface electrode 11, the second obverse-surface electrode 12, the third obverse-surface electrode 13 and the reverse-surface electrode 15 described below are common to the first semiconductor elements 10A and the second semiconductor elements 10B. The first obverse-surface electrode 11, the second obverse-surface electrode 12, and the third obverse-surface electrode 13 are provided on the element obverse surface 101. The first obverse-surface electrode 11, the second obverse-surface electrode 12, and the third obverse-surface electrode 13 are insulated from each other by an insulating film, not shown. The reverse-surface electrode 15 is provided on the element reverse surface 102.

The first obverse-surface electrode 11 is, for example, a gate electrode, through which a drive signal (e.g., gate voltage) for driving the first semiconductor element 10A (the second semiconductor element 10B) is inputted. In each first semiconductor element 10A (each second semiconductor element 10B), the second obverse-surface electrode 12 is, for example, a source electrode, through which a source current flows. The second obverse-surface electrode 12 of the present embodiment has a gate finger 121. The gate finger 121 is made of, for example, a linear insulator extending in the first direction x and divides the second obverse-surface electrode 12 into two parts in the second direction y. The third obverse-surface electrode 13 is, for example, a source sense electrode, through which a source current flows. The reverse-surface electrode 15 is, for example, a drain electrode, through which a drain current flows. The reverse-surface electrode 15 covers the almost entire region of the element reverse surface 102. The reverse-surface electrode 15 is formed, for example, by Ag (silver) plating.

Each of the first semiconductor elements 10A (the second semiconductor elements 10B) switches between a conducting state and a disconnected state in response to a drive signal (gate voltage) inputted to the first obverse-surface electrode 11 (the gate electrode). In the conducting state, a current flows from the reverse-surface electrode 15 (the drain electrode) to the second obverse-surface electrode 12 (the source electrode). In the disconnected state, this current does not flow. That is, each first semiconductor element 10A (each second semiconductor element 10B) performs a switching operation. The semiconductor device A1 uses the switching function of the first semiconductor elements 10A and the second semiconductor elements 10B to convert the DC voltage inputted between the single fourth terminal 44 and the two, i.e., the first and the second terminals 41 and 42 into e.g. AC voltage and outputs the AC voltage from the third terminal 43.

As shown in FIGS. 5, 8, and 9, the semiconductor device A1 includes thermistors 17. The thermistors 17 are used as a temperature detection sensor. The semiconductor device may be configured to include, for example, temperature-sensitive diodes instead of the thermistors 17. Alternatively, the semiconductor device may not include the thermistors 17 or any other temperature sensors.

Support substrate 3:

The support substrate 3 supports the first semiconductor elements 10A and the second semiconductor elements 10B. The specific configuration of the support substrate 3 is not limited. The support substrate is provided by, for example, a DBC (Direct Bonded Copper) substrate or an AMB (Active Metal Brazing) substrate. The support substrate 3 includes an insulating layer 31, a first metal layer 32, and a reverse-surface metal layer 33. The first metal layer 32 includes the first conductive portion 32A and the second conductive portion 32B. The dimension of the support substrate 3 in the thickness direction z is, for example, equal to or greater than 0.4 mm and equal to or less than 3.0 mm.

The insulating layer 31 is made of, for example, a ceramic material having excellent thermal conductivity. Examples of such a ceramic material include SiN (silicon nitride). The insulating layer 31 is not limited to a ceramic material and may be, for example, a sheet of insulating resin. The insulating layer 31 is, for example, rectangular in plan view. The dimension of the insulating layer 31 in the thickness direction z is, for example, equal to or greater than 0.05 mm and equal to or less than 1.0 mm.

The first conductive portion 32A supports the first semiconductor elements 10A, and the second conductive portion 32B supports the second semiconductor elements 10B. The first conductive portion 32A and the second conductive portion 32B are formed on the upper surface (the surface facing the z1 side in the thickness direction z) of the insulating layer 31. The constituent material of the first conductive portion 32A and the second conductive portion 32B includes, for example, Cu (copper). The constituent material may include Al (aluminum) instead of Cu (copper). The first conductive portion 32A and the second conductive portion 32B are spaced apart from each other in the first direction x. The first conductive portion 32A is located on the x1 side in the first direction x of the second conductive portion 32B. The first conductive portion 32A and the second conductive portion 32B are, for example, rectangular in plan view. The first conductive portion 32A and the second conductive portion 32B, together with the first conductive member 5 and the second conductive member 6, form paths for the main circuit current switched by the first semiconductor elements 10A and the second semiconductor elements 10B.

The first conductive portion 32A has a first obverse surface 301A. The first obverse surface 301A is a flat surface facing the z1 side in the thickness direction z. The first obverse surface 301A of the first conductive portion 32A has the first semiconductor elements 10A bonded thereto via a first conductive bonding material 19A. The second conductive portion 32B has a second obverse surface 301B. The second obverse surface 301B is a flat surface facing the z1 side in the thickness direction z. The second obverse surface 301B of the second conductive portion 32B has the second semiconductor elements 10B bonded thereto via a second conductive bonding material 19B. The constituent material of the first conductive bonding material 19A and the second conductive bonding material 19B is not limited, and may be solder, metal paste containing a metal such as Ag (silver), or sintered metal containing a metal such as Ag (silver), for example. The dimension of the first conductive portion 32A and the second conductive portion 32B in the thickness direction z is, for example, equal to or greater than 0.1 mm and equal to or less than 1.5 mm.

The reverse-surface metal layer 33 is formed on the lower surface (the surface facing the z2 side in the thickness direction z) of the insulating layer 31. The constituent material of the reverse-surface metal layer 33 is the same as that of the first metal layer 32. The reverse-surface metal layer 33 has a reverse surface 302. The reverse surface 302 is a flat surface facing the z2 side in the thickness direction z. The reverse surface 302 is exposed from the sealing resin 8. The reverse-surface metal layer 33 overlaps with both of the first conductive portion 32A and the second conductive portion 32B in plan view.

Heat dissipation member 2:

As shown in FIGS. 2, 6, 10 to 13, and 16 to 26, the heat dissipation member 2 is disposed on the reverse surface 302 of the reverse-surface metal layer 33 of the support substrate 3. The heat dissipation member 2 includes a plurality of first protrusions 21. The heat dissipation member 2 of the present embodiment further includes a plurality of second protrusions 22. FIGS. 21 to 26 show a portion of the heat dissipation member 2 for the convenience of explanation. The material of the heat dissipation member 2 is not limited. The heat dissipation member may be made by using a metal plate material, for example. The metal plate material contains a metal, such as Cu (copper), Al (aluminum) or stainless steel, or an alloy of these metals.

Each of the first protrusions 21 protrudes toward the z2 side in the thickness direction z. The first protrusions 21 are arranged in a matrix along a plane containing the first direction x and the second direction y. The matrix arrangement in the present disclosure refers to an arrangement that has certain regularity along the above-described plane and includes, for example, an arrangement in a grid pattern along the first direction x and the second direction y and an arrangement in a staggered pattern.

Each of the second protrusions 22 protrudes toward the z2 side in the thickness direction z. The second protrusions 22 are arranged in a matrix along a plane containing the first direction x and the second direction y. The definition of the matrix arrangement for the second protrusions 22 is the same as that for the first protrusions 21.

Each of the first protrusions 21 has a first base portion 211, a second base portion 212, a first standing portion 213, a second standing portion 214, and a first end portion 215. The first base portion 211 and the second base portion 212 are spaced apart from each other in the first direction x. In the present embodiment, the first base portion 211 of one of two first protrusions 21 adjacent to each other in the first direction x is connected to the second base portion 212 of the other one of the first protrusions, forming an integral portion. The shapes of the first base portion 211 and the second base portion 212 are not limited, and rectangular shapes elongated in the second direction y as viewed in the thickness direction z in the present embodiment.

The first base portion 211 and the second base portion 212 are each bonded to the reverse surface 302. The method for bonding the first base portion 211 and the second base portion 212 is not limited, and a welding method such as laser welding, a method using a bonding layer such as an adhesive or solder, or other methods such as ultrasonic bonding or solid-phase diffusion bonding may be selected as appropriate. In the present embodiment, the first base portion 211 and the second base portion 212 are bonded to the reverse surface 302 by laser welding. As a result, a plurality of weld portions M are formed by a part of each first base portion 211, a part of each second base portion 212, and parts of the reverse surface 302 (the reverse-surface metal layer 33). In the illustrated example, two weld portions M are formed in a region where one first base portion 211 and one second base portion 212 are connected. The two weld portions M are aligned in the second direction y.

The first end portion 215 is located between the first base portion 211 and the second base portion 212 in the first direction x. The first end portion 215 is located on the z2 side from the first base portion 211 and the second base portion 212 in the thickness direction z. The first end portion 215 in the present embodiment has the shape of a flat plate. The shape of the first end portion 215 is not limited, and may be a rectangular shape elongated in the second direction y as viewed in the thickness direction z.

The first standing portion 213 is connected to the first base portion 211 and the first end portion 215. Specifically, the first standing portion 213 is connected to the edge on the x2 side in the first direction x of the first base portion 211 and the edge on the x1 side in the first direction x of the first end portion 215. The shape of the first standing portion 213 is not limited, and is a rectangular shape as viewed in the first direction x in the present embodiment.

The second standing portion 214 is connected to the second base portion 212 and the first end portion 215. Specifically, the second standing portion 214 is connected to the edge on the x1 side in the first direction x of the second base portion 212 and the edge on the x2 side in the first direction x of the first end portion 215. The shape of the second standing portion 214 is not limited, and is rectangular shape as viewed in the first direction x in the present embodiment.

The size of each portion of the first protrusion 21 is not limited. In the present embodiment, the size of the first protrusion 21 in the thickness direction z is greater than the distance between the first standing portion 213 and the second standing portion 214 in the first direction x.

Each of the second protrusions 22 has a third base portion 221, a fourth base portion 222, a third standing portion 223, a fourth standing portion 224, and a second end portion 225.

The third base portion 221 and the fourth base portion 222 are spaced apart from each other in the first direction x. In the present embodiment, the third base portion 221 of one of two second protrusions 22 adjacent to each other in the first direction x is connected to the fourth base portion 222 of the other one of the second protrusions, forming an integral portion. The shapes of the third base portion 221 and the fourth base portion 222 are not limited, and rectangular shapes elongated in the second direction y as viewed in the thickness direction z in the present embodiment.

The third base portion 221 and the fourth base portion 222 are connected to the first end portions 215 of the first protrusions 21. Specifically, the third base portion 221 and the fourth base portion 222 are each located between first protrusions 21 adjacent to each other in the second direction y and connected to the first end portions 215 of these first protrusions. The positions of the third base portion 221 and the fourth base portion 222 in the thickness direction z are the same (or approximately the same) as that of the first end portion 215. That is, in the present embodiment, the third base portions 221 and the fourth base portions 222 of the plurality of second protrusions 22 and the first end portions 215 of the plurality of first protrusions 21 are connected to each other to form strip-shaped portions extending in the second direction y.

The second end portion 225 is located between the third base portion 221 and the fourth base portion 222 in the first direction x. The second end portion 225 is located on the z2 side from the third base portion 221 and the fourth base portion 222 in the thickness direction z. The second end portion 225 in the present embodiment has the shape of a flat plate. The shape of the second end portion 225 is not limited, and may be a rectangular shape elongated in the second direction y as viewed in the thickness direction z. The second end portion 225 is located between the first base portions 211 of first protrusions 21 adjacent to each other in the second direction y and between the second base portions 212 of the first protrusions 21 adjacent to each other in the second direction y, as viewed in the thickness direction z.

The third standing portion 223 is connected to the third base portion 221 and the second end portion 225. Specifically, the third standing portion 223 is connected to the edge on the x2 side in the first direction x of the third base portion 221 and the edge on the x1 side in the first direction x of the second end portion 225. The shape of the third standing portion 223 is not limited, and is a rectangular shape as viewed in the first direction x in the present embodiment. The fourth standing portion 224 is connected to the fourth base portion 222 and the second end portion 225. Specifically, the fourth standing portion 224 is connected to the edge on the x1 side in the first direction x of the fourth base portion 222 and the edge on the x2 side in the first direction x of the second end portion 225. The shape of the fourth standing portion 224 is not limited, and isa rectangular shape as viewed in the first direction x in the present embodiment.

The size of each portion of the second protrusion 22 is not limited. In the present embodiment, the size of the second protrusion 22 in the thickness direction z is greater than the distance between the third standing portion 223 and the fourth standing portion 224 in the first direction x. In the present embodiment, the size of the second protrusion 22 in the thickness direction z is the same (or approximately the same) as the size of the first protrusion 21 in the thickness direction z. However, the size of the first protrusion 21 in the thickness direction z and the size of the second protrusion 22 in the thickness direction z may differ from each other.

FIG. 27 shows the step for forming the heat dissipation member 2 in an example of the manufacturing method of the semiconductor device A1. In the figure, (a) shows a part of the heat dissipation member 2, and (b) and (c) show a metal plate material 20 used for forming the part of the heat dissipation member 2 shown in (a). In the figure, (c) is a plan view of the metal plate material 20. The metal plate material 20 is formed with a plurality of cutting lines 201. In the figure, (b) is a z-x sectional view containing the cutting lines 201.

The cutting lines 201 penetrate the metal plate material 20 in the thickness direction z. The cutting lines 201, which are straight lines in the present embodiment, extend in the first direction x. The cutting lines 201 are arranged in a matrix along an x-y plane.

Of the metal plate material 20, the regions located between the cutting lines 201 adjacent to each other in the first direction x are the regions to become the first end portions 215 or the third base portions 221 and the fourth base portions 222. Of the metal plate material 20, the regions located between the cutting lines 201 adjacent to each other in the second direction y are the regions to become the first base portion 211, the second base portion 212, the first standing portion 213 and the second standing portion 214 or the regions to become the third standing portion 223, the fourth standing portion 224 and the second end portion 225.

The metal plate material 20 is bent at regions that will become the first base portions 211, the second base portions 212, the first standing portions 213 and the second standing portions 214 so as to protrude toward the z1 side in the thickness direction z, whereby the plurality of first protrusions 21 are formed. Also, the metal plate material 20 is bent at regions that will become the third standing portions 223, the fourth standing portions 224 and the second end portions 225 so as to protrude toward the z2 side in the thickness direction z, whereby the plurality of second protrusions 22 are formed. By this bending process, the metal plate material 20 shown in (b) in the figure becomes the heat dissipation member 2 shown in (a) in the figure. As understood from (a) and (b) in the figure, when the metal plate material 20 is subjected to the bending process to become the heat dissipation member 2, its size in the first direction x reduces. That is, the size in the first direction x of the heat dissipation member 2 is smaller than the size in the first direction x of the metal plate material 20 before the bending process.

After the heat dissipation member 2 is formed, the step of disposing the heat dissipation member 2 on the reverse surface 302 of the support substrate 3 is performed. In this step, the first base portions 211 and the second base portions 212 of the heat dissipation member 2 are bonded to the reverse surface 302 by, for example, laser welding. This provides a configuration in which the heat dissipation member 2 and the reverse surface 302 are in direct contact with each other with no adhesive or the like present between the heat dissipation member 2 and the reverse surface 302.

First terminal 41, Second terminal 42, Third terminal 43, Fourth terminal 44:

Each of the first terminal 41, the second terminal 42, the third terminals 43, and the fourth terminal 44 is made of a metal plate. The metal plate contains, for example, Cu (copper) or a Cu (copper) alloy. In the example shown in FIGS. 1 to 5, 8, 9, and 11, the semiconductor device A1 has one each of the first terminal 41, the second terminal 42 and the fourth terminal 44, and two third terminals 43. However, the number of the terminals is not limited.

The DC voltage to be converted is inputted to the first terminal 41, the second terminal 42, and the fourth terminal 44. The fourth terminal 44 is a positive electrode (P terminal), and each of the first terminal 41 and the second terminal 42 is a negative electrode (N terminal). The AC voltage converted by the first semiconductor elements 10A and the second semiconductor elements 10B is outputted from the third terminals 43. Each of the first terminal 41, the second terminal 42, the third terminals 43, and the fourth terminal 44 includes a portion covered with the sealing resin 8 and a portion exposed from the sealing resin 8.

As shown in FIG. 13, the fourth terminal 44 is conductively bonded to the first conductive portion 32A. The methods of conductive bonding are not limited, and methods such as ultrasonic bonding, laser bonding, welding, or other methods using solder, metal paste, sintered silver or the like are used as appropriate. As shown in FIGS. 8 and 9, the fourth terminal 44 is located on the x1 side in the first direction x with respect to the first semiconductor elements 10A and the first conductive portion 32A. The fourth terminal 44 is electrically connected to the first conductive portion 32A and also electrically connected to the reverse-surface electrode 15 (drain electrode) of each first semiconductor element 10A via the first conductive portion 32A.

The first terminal 41 and the second terminal 42 are electrically connected to the second conductive member 6. In the present embodiment, the first terminal 41 and the second conductive member 6 are integrally formed. “The first terminal 41 and the second conductive member 6 are integrally formed” means that they are formed, for example, by cutting and bending a single metal plate material, and no bonding material or the like for bonding them together is included. Also, in the present embodiment, the second terminal 42 and the second conductive member 6 are integrally formed. The first terminal 41 and the second terminal 42 can have other configurations as long as they are electrically connected to the second conductive member 6, and may include bond portions where these terminals are bonded to the second conductive member, unlike the present embodiment. As shown in FIGS. 5 and 8, the first terminal 41 and the second terminal 42 are located on the x1 side in the first direction x with respect to the first semiconductor elements 10A and the first conductive portion 32A. The first terminal 41 and the second terminal 42 are electrically connected to the second conductive member 6 and electrically connected to the second obverse-surface electrode 12 (source electrode) of each second semiconductor element 10B via the second conductive member 6.

As shown in FIGS. 1 to 5 and 11, in the semiconductor device A1, the first terminal 41, the second terminal 42, and the fourth terminal 44 protrude from the sealing resin 8 toward the x1 side in the first direction x. The first terminal 41, the second terminal 42, and the fourth terminal 44 are spaced apart from each other. The first terminal 41 and the second terminal 42 are located opposite to each other with the fourth terminal 44 interposed therebetween in the second direction y. The first terminal 41 is located on the y1 side in the second direction y of the fourth terminal 44, and the second terminal 42 is located on the y2 side in the second direction y of the fourth terminal 44. The first terminal 41, the second terminal 42, and the fourth terminal 44 overlap with each other as viewed in the second direction y.

As understood from FIGS. 8, 9, and 12, the two third terminals 43 are conductively bonded to the second conductive portion 32B. The methods of conductive bonding are not limited, and methods such as ultrasonic bonding, laser bonding, welding, or other methods using solder, metal paste, sintered silver or the like are used as appropriate. As shown in FIG. 8, the two third terminals 43 are located on the x2 side in the first direction x with respect to the second semiconductor elements 10B and the second conductive portion 32B. Each third terminal 43 is electrically connected to the second conductive portion 32B and electrically connected to the reverse-surface electrode 15 (drain electrode) of each second semiconductor element 10B via the second conductive portion 32B. The number of third terminals 43 is not limited to two, and may be one, or three or more. When only one third terminal 43 is provided, the third terminal 43 is preferably connected to the middle part in the second direction y of the second conductive portion 32B.

The control terminals 45 are pin-shaped terminals for controlling the first semiconductor elements 10A and the second semiconductor elements 10B. The control terminals 45 include a plurality of first control terminals 46A to 46E and a plurality of second control terminals 47A to 47D. The first control terminals 46A to 46E are used to control the first semiconductor elements 10A, for example. The second control 47A to terminals 47D are used to control the second semiconductor elements 10B, for example.

First control terminals 46A to 46E:

The first control terminals 46A to 46E are spaced apart from each other in the second direction y. As shown in FIGS. 8, 13, and 20, the first control terminals 46A to 46E are supported on the first conductive portion 32A via the control terminal support 48 (the first support portion 48A, described later). As shown in FIGS. 5 and 8, the first control terminals 46A to 46E are located between the first semiconductor elements 10A and the first, the second, and the fourth terminals 41, 42, and 44 in the first direction x.

The first control terminal 46A is a terminal (a gate terminal) for inputting a drive signal for the first semiconductor elements 10A. A drive signal for driving the first semiconductor elements 10A is inputted (e.g., a gate voltage is applied) to the first control terminal 46A.

The first control terminal 46B is a terminal (a source sense terminal) for detecting a source signal of the first semiconductor elements 10A. The voltage applied to the second obverse-surface electrode 12 (the source electrode) of each first semiconductor element 10A (the voltage corresponding to the source current) is detected from the first control terminal 46B.

The first control terminal 46C and the first control terminal 46D are terminals electrically connected to a thermistor 17.

The first control terminal 46E is a terminal (a drain sense terminal) for detecting a drain signal of the first semiconductor elements 10A. The voltage applied to the reverse-surface electrode 15 (the drain electrode) of each first semiconductor element 10A (the voltage corresponding to the drain current) is detected from the first control terminal 46E.

The second control terminals 47A to 47D are spaced apart from each other in the second direction y. As shown in FIGS. 8 and 13, the second control terminals 47A to 47D are supported on the second conductive portion 32B via the control terminal support 48 (the second support portion 48B, described later). As shown in FIGS. 5 and 8, the second control terminals 47A to 47D are located between the second semiconductor elements 10B and the two third terminals 43 in the first direction x.

The second control terminal 47A is a terminal (a gate terminal) for inputting a drive signal for the second semiconductor elements 10B. A drive signal for driving the second semiconductor elements 10B is inputted (e.g., a gate voltage is applied) to the second control terminal 47A. The second control terminal 47B is a terminal (a source sense terminal) for detecting a source signal of the second semiconductor elements 10B. The voltage applied to the second obverse-surface electrode 12 (the source electrode) of each second semiconductor element 10B (the voltage corresponding to the source current) is detected from the second control terminal 47B. The second control terminal 47C and the second control terminal 47D are terminals electrically connected to a thermistor 17.

Each of the control terminals 45 (the first control terminals 46A to 46E and the second control terminals 47A to includes a holder 451 and a metal pin 452. 47E)

The holders 451 are made of an electrically conductive material. As shown in FIGS. 14 and 15, the holders 451 are bonded to the control terminal support 48 (the first metal layer 482, described later) via a conductive bonding material 459. Each holder 451 includes a tubular portion, an upper flange portion, and a lower flange portion. The upper flange portion is connected to the top of the tubular portion, and the lower flange portion is connected to the bottom of the tubular portion. A metal pin 452 is inserted in at least the upper flange portion and the tubular portion of each holder 451. The holders 451 are covered with the sealing resin 8 (second projections 852, described later).

Each metal pin 452 is a bar-shaped member extending in the thickness direction z. The metal pin 452 is supported by being press-fitted into a holder 451. The metal pin 452 is electrically connected to the control terminal support 48 (the first metal layer 482, described later) at least via the holder 451. In the case where the lower end of the metal pin 452 (the end on the z2 side in the thickness direction z) is in contact with the conductive bonding material 459 within the through-hole of the holder 451 like the example shown in FIGS. 14 and 15, the metal pin 452 is electrically connected to the control terminal support 48 via the conductive bonding material 459.

Control terminal support 48:

The control terminal support 48 supports the control terminals 45. The control terminal support 48 is interposed between the first and the second obverse surfaces 301A and 301B and the control terminals 45 in the thickness direction Z.

The control terminal support 48 includes a first support portion 48A and a second support portion 48B. The first support portion 48A is disposed on the first conductive portion 32A and supports the first control terminals 46A to 46E of the control terminals 45. As shown in FIG. 14, the first support portion 48A is bonded to the first conductive portion 32A via a bonding material 49. The bonding material 49 may be electrically conductive or insulating, and may be solder, for example. The second support portion 48B is disposed on the second conductive portion 32B and supports the second control terminals 47A to 47D of the control terminals 45. As shown in FIG. 15, the second support portion 48B is bonded to the second conductive portion 32B via a bonding material 49.

The control terminal support (each of the first support portion 48A and the second support portion 48B) is provided by, for example, a DBC (Direct Bonded Copper) substrate. The control terminal support 48 includes an insulating layer 481, a first metal layer 482, and a second metal layer 483 laminated on top of each other.

The insulating layer 481 is made of, for example, a ceramic material. The insulating layer 481 may be rectangular in plan view.

As shown in FIGS. 14 and 15, the first metal layer 482 is formed on the upper surface of the insulating layer 481. Each control terminal 45 stands on the first metal layer 482. The first metal layer 482 contains, for example, Cu (copper) or a Cu (copper) alloy. As shown in FIG. 8, the first metal layer 482 includes a first portion 482A, a second portion 482B, a third portion 482C, a fourth portion 482D, a fifth portion 482E, and a sixth portion 482F. The first portion 482A, the second portion 482B, the third portion 482C, the fourth portion 482D, the fifth portion 482E, and the sixth portion 482F are spaced apart and insulated from each other.

The first portion 482A, to which a plurality of wires 71 are bonded, is electrically connected to the first obverse-surface electrodes 11 (gate electrodes) of the first semiconductor elements 10A (the second semiconductor elements 10B) via the wires 71. A plurality of wires 73 are connected to the first portion 482A and the sixth portion 482F. Thus, the sixth portion 482F is electrically connected to the first obverse-surface electrodes 11 (gate electrodes) of the first semiconductor elements 10A (the second semiconductor elements 10B) via the wires 73 and the wires 71. As shown in FIG. 8, the first control terminal 46A is bonded to the sixth portion 482F of the first support portion 48A, and the second control terminal 47A is bonded to the sixth portion 482F of the second support portion 48B.

The second portion 482B, to which a plurality of wires 72 are bonded, is electrically connected to the third obverse-surface electrodes 13 (source sense electrodes) of the first semiconductor elements 10A (the second semiconductor elements 10B) via the wires 72. As shown in FIG. 8, the first control terminal 46B is bonded to the second portion 482B of the first support portion 48A, and the second control terminal 47B is bonded to the second portion 482B of the second support portion 48B.

A thermistor 17 is bonded to the third portion 482C and the fourth portion 482D. As shown in FIG. 8, the first control terminals 46C and 46D are bonded to the third portion 482C and the fourth portion 482D, respectively, of the first support portion 48A. The second control terminals 47C and 47D are bonded to the third portion 482C and the fourth portion 482D, respectively, of the second support portion 48B.

The fifth portion 482E of the first support portion 48A, to which a wire 74 is bonded, is electrically connected to the first conductive portion 32A via the wire 74. As shown in FIG. 8, the first control terminal 46E is bonded to the fifth portion 482E of the first support portion 48A. The fifth portion 482E of the second support portion 48B is not electrically connected to other components. Each of the wires 71 to 74 is, for example, a bonding wire. The constituent material of the wires 71 to 74 includes, for example, one of Au (gold), Al (aluminum) or Cu (copper).

As shown in FIGS. 14 and 15, the second metal layer 483 is formed on the lower surface of the insulating layer 481. As shown in FIG. 14, the second metal layer 483 of the first support portion 48A is bonded to the first conductive portion 32A via a bonding material 49. As shown in FIG. 15, the second metal layer 483 of the second support portion 48B is bonded to the second conductive portion 32B via a bonding material 49.

First conductive member 5, Second conductive member 6:

The first conductive member 5 and the second conductive member 6, together with the first conductive portion 32A and the second conductive portion 32B, constitute a path for the main circuit current switched by the first semiconductor elements 10A and the second semiconductor elements 10B. The first conductive member 5 and the second conductive member 6 are spaced apart from the first obverse surface 301A and the second obverse surface 301B to the z1 side in the thickness direction z and overlap with the first obverse surface 301A and the second obverse surface 301B in plan view. In the present embodiment, each of the first conductive member 5 and the second conductive member 6 is made of a metal plate. The metal includes, for example, Cu (copper) or a Cu (copper) alloy. Specifically, the first conductive member 5 and the second conductive member 6 are metal plates that are bent as appropriate.

The first conductive member 5 is connected to the second obverse-surface electrode 12 (the source electrode) of each first semiconductor element 10A and the second conductive portion 32B to electrically connect the second obverse-surface electrode 12 of each first semiconductor element 10A and the second conductive portion 32B. The first conductive member 5 constitutes a path for the main circuit current switched by the first semiconductor elements 10A. As shown in FIGS. 7 and 8, the first conductive member 5 includes a main portion 51, a plurality of first bond portions 52, and a plurality of second bond portions 53.

The main portion 51 is located between the first semiconductor elements 10A and the second conductive portion 32B in the first direction x and has a strip shape extending in the second direction y in plan view. The main portion 51 overlaps with both of the first conductive portion 32A and the second conductive portion 32B in plan view and is spaced apart from the first obverse surface 301A and the second obverse surface 301B to the z1 side in the thickness direction z. As shown in FIG. 16, the main portion 51 is located on the z2 side in the thickness direction z with respect to the third path portion 66 and the fourth path portion 67 of the second conductive member 6, described later, and located closer to the first obverse surface 301A and the second obverse surface 301B than are the third path portion 66 and the fourth path portion 67.

In the present embodiment, the main portion 51 is parallel to the first obverse surface 301A and the second obverse surface 301B.

As shown in FIG. 8, the main portion 51 extends continuously in the second direction y to correspond to the areas in which the first semiconductor elements 10A are disposed. In the present embodiment, the main portion 51 is formed with a plurality of first openings 514 as shown in FIGS. 7, 8, and 13. Each of the first openings 514 is a for example, in the thickness through-hole penetrating, direction z (the plate thickness direction of the main portion 51). The first openings 514 are arranged at intervals in the second direction y. The first openings 514 are provided to correspond to the first semiconductor elements 10A, respectively. In the present embodiment, four first openings 514 are provided in the main portion 51, and these first openings 514 and the plurality of (four) first semiconductor elements 10A are at the same positions in the second direction y.

In the present embodiment, each of the first openings 514 overlaps with the gap between the first conductive portion 32A and the second conductive portion 32B in plan view as shown in FIGS. 8 and 13. The first openings 514 are formed to facilitate the flow of the resin material between the upper side (z1 side in the thickness direction z) and the lower side (z2 side in the thickness direction z) at or near the main portion 51 (the first conductive member 5) when the flowable resin material is injected to form the sealing resin 8.

As shown in FIG. 8, the first bond portions 52 and the second bond portions 53 are connected to the main portion 51 and disposed to correspond to the first semiconductor elements 10A. Specifically, each of the first bond portions 52 is located on the x1 side in the first direction x with respect to the main portion 51. Each of the second bond portions 53 is located on the x2 side in the first direction x with respect to the main portion 51. As shown in FIG. 14, each of the first bond portions 52 and the second obverse-surface electrode 12 of a relevant one of the first semiconductor elements 10A are bonded via a conductive bonding material 59. Each of the second bond portions 53 and the second conductive portion 32B are bonded via a conductive bonding material 59. The constituent material of the conductive bonding materials 59 is not particularly limited, and may be solder, metal paste or sintered metal, for example. In the present embodiment, each of the first bond portions 52 has two parts separated in the second direction y. These two parts are bonded to the second obverse-surface electrode the first 12 of semiconductor element 10A to flank the gate finger 121 of the second obverse-surface electrode 12 in the second direction y.

The second conductive member 6 electrically connects the second obverse-surface electrode 12 (source electrode) of each second semiconductor element 10B and the first and the second terminals 41 and 42. The second conductive member 6 is integrally formed with the first terminal 41 and the second terminal 42. The second conductive member 6 constitutes a path for the main circuit current switched by the second semiconductor elements 10B. As shown in FIGS. 3, 5 to 7, 12, 13, and 16 to 18, the second conductive member 6 includes a plurality of third bond portions 61, a first path portion 64, a second path portion 65, a plurality of third path portions 66, and a fourth path portion 67. Also, in the illustrated example, the second conductive member 6 includes a first stepped portion 602 and a second stepped portion 603.

The third bond portions 61 are individually bonded to the second semiconductor elements 10B. Each of the third bond portions 61 and the second obverse-surface electrode 12 of a relevant second semiconductor element 10B are bonded via a conductive bonding material 69. The constituent material of the conductive bonding materials 69 is not particularly limited, and may be solder, metal paste or sintered metal, for example. In the present embodiment, each third bond portion 61 has two flat sections 611 and two first inclined sections 612.

The two flat sections 611 are aligned in the second direction y. The two flat sections 611 are spaced apart from each other in the second direction y. The shape of the flat sections 611 is not limited, but is rectangular in the illustrated example. The two flat sections are bonded to the electrode second obverse-surface 12 of the second semiconductor element 10B to flank the gate finger 121 of the second obverse-surface electrode 12 in the second direction y.

The two first inclined sections 612 are connected to the outer edges of the two flat sections 611 in the second direction y. That is, the first inclined section 612 located on the y1 side in the second direction y is connected to the edge on the y1 side in the second direction y of the flat section 611 located on the y1 side in the second direction y. Also, the first inclined section 612 located on the y2 side in the second direction y is connected to the edge on the y2 side in the second direction y of the flat section 611 located on the y2 side in the second direction y. Each first inclined section 612 is inclined to extend toward the z1 side in the thickness direction z as it becomes farther away from the flat section 611 in the second direction y.

The first path portion 64 is interposed between the third bond portions 61 and the first terminal 41. In the illustrated example, the first path portion 64 is connected to the first terminal 41 via the first stepped portion 602.

The first path portion 64 overlaps with the first conductive portion 32A in plan view. The first path portion 64 has a shape extending in the first direction x as a whole. The first path portion 64 includes a first strip portion 641 and a first extension portion 643. The first strip portion 641 is located on the x2 side in the first direction x with respect to the first terminal 41 and is generally parallel to the first obverse surface 301A. The first strip portion 641 has a shape extending in the first direction x as a whole. In the illustrated example, the first strip portion 641 has a recess 649. The recess 649 is the portion where a part of the first strip portion 641 is recessed toward the y1 side in the second direction y. In FIG. 7, the first conductive portion 32A is visible through the recess 649.

The first extension portion 643 extends toward the z2 side in the thickness direction z from the side edge of the first strip portion 641 on the y1 side in the second direction y. The first extension portion 643 is spaced apart from the first conductive portion 32A. In the illustrated example, the first extension portion 643 extends along the thickness direction z and has a rectangular shape elongated in the first direction x. Incidentally, the first path portion 64 may not have the first extension portion 643.

The second path portion 65 is interposed between the third bond portions 61 and the second terminal 42. In the illustrated example, the second path portion 65 is connected to the second terminal 42 via the second stepped portion 603. The second path portion 65 overlaps with the first conductive portion 32A in plan view. The second path portion 65 has a shape extending in the first direction x as a whole.

The second path portion 65 includes a second strip portion 651 and a second extension portion 653. The second strip portion 651 is located on the x2 side in the first direction x with respect to the second terminal 42 and is generally parallel to the first obverse surface 301A. The second strip portion 651 has a shape extending in the first direction x as a whole. In the illustrated example, the second strip portion 651 has a recess 659. The recess 659 is the portion where a part of the second strip portion 651 is recessed toward the y2 side in the second direction y. In FIG. 7, the first conductive portion 32A is visible through the recess 659.

The second extension portion 653 extends toward the z2 side in the thickness direction z from the side edge of the second strip portion 651 on the y2 side in the second direction y. The second extension portion 653 is spaced apart from the first conductive portion 32A. In the illustrated example, the second extension portion 653 extends along the thickness direction z and has a rectangular shape elongated in the first direction x. Incidentally, the second path portion 65 may not have the second extension portion 653.

The third path portions 66 are individually connected to the third bond portions 61. The third path portions 66, each extending in the first direction x, are spaced apart from each other in the second direction y. The number of third path portions 66 is not limited. In the illustrated example, five third path portions 66 are disposed. Each of the third path portions 66 is disposed to be located between the second semiconductor elements 10B in the second direction y or on the outer side of the second semiconductor elements 10B in the second direction y.

The two third path portions 66 located on opposite outer sides in the second direction y are formed with recesses 669. The recesses 669 are recessed from the inner side toward the outer side in the second direction y. In the illustrated example, one recess 669 is formed in each of the two third path portions 66. In FIG. 5, the second conductive portion 32B is visible through the recesses 669.

In the present embodiment, one third bond portion 61 is disposed between two adjacent third path portions 66 in the second direction y. In each third bond portion 61, the first inclined section 612 located on the y1 side in the second direction y is connected to one of the two third path portions 66 adjacent in the second direction y that is located on the y1 side in the second direction y. In each third bond portion 61, the first inclined section 612 located on the y2 side in the second direction y is connected to one of the two third path portions 66 adjacent in the second direction y that is located on the y2 side in the second direction y.

The fourth path portion 67 is connected to the ends on the x1 side in the first direction x of the plurality of third path portions 66. The fourth path portion 67 has a shape elongated in the second direction y. The fourth path portion 67 is connected to the ends on the x2 side in the first direction x of the first strip portion 641 of the first path portion 64 and the second strip portion 651 of the second path portion 65. In the illustrated example, the first path portion 64 is connected to the end on the y1 side in the second direction y of the fourth path portion 67. The second path portion 65 is connected to the end on the y2 side in the second direction y of the fourth path portion 67.

Sealing resin 8:

The sealing resin 8 covers the first semiconductor elements 10A, the second semiconductor elements 10B, the support substrate 3 (excluding the reverse surface 302), a part of each of the first terminal 41, the second terminal 42, the third terminals 43 and the fourth terminal 44, a part of each of the control terminals 45, the control terminal support 48, the first conductive member 5, the second conductive member 6, and the wires 71 to 74. The sealing resin 8 is made of, for example, black epoxy resin. The sealing resin 8 is formed by, for example, molding. The sealing resin 8 has dimensions of, for example, about 35 mm to 60 mm in the first direction x, about 35 mm to 50 mm in the second direction y, and about 4 mm to 15 mm in the thickness direction z. These dimensions are the size of the largest portion along each direction. The sealing resin 8 has a resin obverse surface 81, a resin reverse surface 82, and a plurality of resin side surfaces 831 to 834.

As shown in FIGS. 10, 12, and 18, the resin obverse surface 81 and the resin reverse surface 82 are spaced apart from each other in the thickness direction z. The resin obverse surface 81 faces the z1 side in the thickness direction z, and the resin reverse surface 82 faces the z2 side in the thickness direction z. The control terminals 45 (the first control terminals 46A to 46E and the second control terminals 47A to 47D) protrude from the resin obverse surface 81. As shown in FIG. 11, the resin reverse surface 82 has a frame shape surrounding the reverse surface 302 of the support substrate 3 (the lower surface of the reverse-surface metal layer 33) in plan view. The reverse surface 302 of the support substrate 3 is exposed at the resin reverse surface 82 and may be flush with the resin reverse surface 82. Each of the resin side surfaces 831 to 834 is connected to the resin obverse surface 81 and the resin reverse surface 82 and disposed between these surfaces in the thickness direction z. As shown in FIG. 4, the resin side surface 831 and the resin side surface 832 are spaced apart from each other in the first direction x. The resin side surface 831 faces the x2 side in the first direction x, and the resin side surface 832 faces the x1 side in the first direction x. The two third terminals 43 protrude from the resin side surface 831, and the first terminal 41, the second terminal 42 and the fourth terminal 44 protrude from the resin side surface 832. As shown in FIG. 4, the resin side surface 833 and the resin side surface 834 are spaced apart from each other in the second direction y. The resin side surface 833 faces the y2 side in the second direction y, and the resin side surface 834 faces the y1 side in the second direction y.

As shown in FIG. 4, the resin side surface 832 is formed with a plurality of recesses 832a. Each recess 832a is a portion recessed in the first direction x in plan view. The recesses 832a include one formed between the first terminal 41 and the fourth terminal 44 and one formed between the second terminal 42 and the fourth terminal 44 in plan view. The recesses 832a are provided to increase the creepage distance between the first terminal 41 and the fourth terminal 44 along the resin side surface 832 and the creepage distance between the second terminal 42 and the fourth terminal 44 along the resin side surface 832.

As shown in FIGS. 12 and 13, the sealing resin 8 has a plurality of first projections 851, a plurality of second projections 852, and a resin void portion 86.

The first projections 851 protrude from the resin obverse surface 81 in the thickness direction z. The first projections 851 are disposed at the four corners of the sealing resin 8 in plan view. Each first projection 851 has a projection end surface 851a at its extremity (the end on the z1 side in the thickness direction z). The projection end surfaces 851a of the first projections 851 are generally parallel to the resin obverse surface 81 and located on the same plane (x-y plane). Each first projection 851 may have the shape of a hollow conical frustum with a bottom, for example. The first projections 851 are used as spacers when the semiconductor device A1 is mounted on a control circuit board or the like of a device configured to use the power produced by the semiconductor device A1. Each of the first projections 851 has a recess 851b and an inner wall surface 851c formed around the recess 851b. The shape of each first projection 851 may be columnar, and preferably cylindrical. Preferably, the shape of the recess 851b is cylindrical, and the inner wall surface 851c has the shape of a single perfect circle in plan view.

The sealing resin 8 has grooves 89. The grooves 89 are recessed from the resin reverse surface 82 toward the z1 side in the thickness direction z. The grooves 89 extend across the resin reverse surface 82 in the second direction y. In the illustrated example, the sealing resin 8 has two grooves 89. The two grooves 89 are spaced apart from each other in the first direction x. The reverse-surface metal layer 33 (the reverse surface 302) is located between the two grooves 89.

The semiconductor device A1 may be mechanically fixed to a control circuit board or the like by screwing, for example. In such a case, female threads can be formed on the inner wall surfaces 851c of the recesses 851b of the first projections 851. Insert nuts may be embedded in the recesses 851b of the first projections 851.

As shown in FIG. 13, the second projections 852 protrude from the resin obverse surface 81 in the thickness direction Z. The second projections 852 overlap with the control terminals 45 in plan view. The metal pin 452 of each of the control terminals 45 protrudes from one of the second projections 852. Each second projection 852 has the shape of a conical frustum. The second projection 852 covers the holder 451 and a part of the metal pin 452.

As shown in FIGS. 29 and 30, the electric power conversion unit B1 includes the semiconductor device A1 and a cooling device 9.

The cooling device 9 is disposed on the z2 side in the thickness direction z of the semiconductor device A1. The cooling device 9 has a housing 91.

The housing 91 is a box-shaped member made of metal or resin, for example. The housing 91 houses the heat dissipation member 2. In the present embodiment, the housing 91 is attached to the semiconductor device A1 via a sealing material 919. The sealing material 919 is disposed between an end of the housing 91 and the resin reverse surface 82 of the sealing resin 8 and maintains the airtightness of the internal space of the housing 91.

The housing 91 is filled with a cooling medium Cm. The cooling medium Cm flows within the housing 91. In the present embodiment, the cooling device 9 has a supply section 92 and a discharge section 93. The supply section 92 and the discharge section 93 are attached to opposite sides in the first direction x of the housing 91. The cooling medium Cm is supplied from the supply section 92 to the housing 91. The cooling medium Cm that has flowed through the housing 91 is discharged from the discharge section 93. In this way, the cooling medium Cm flows in the second direction y in the housing 91. Here, “the cooling medium Cm flows in the second direction y” does not exclusively mean that the flow velocity component in the second direction y exists, but also means the state in which the cooling medium Cm moves in the second direction y as a whole while including flow velocity components in the first direction x and in the thickness direction z.

Next, the effects of the present embodiment will be described.

The heat dissipation member 2 includes a plurality of first protrusions 21. The first protrusions 21 protrude from the reverse surface 302 toward the z2 side in the thickness direction z. The first protrusions 21 are arranged in a matrix along a plane containing the first direction x and the second direction y. With such a configuration, during the cooling using the cooling medium Cm, the heat transferred from the first semiconductor elements 10A and the second semiconductor elements 10B to the heat dissipation member 2 through the support substrate 3 can be efficiently transferred to the cooling medium Cm. Therefore, the heat from the first semiconductor elements 10A and the second semiconductor elements 10B can be quickly dissipated.

As explained with reference to FIG. 27, the heat dissipation member 2 has a reduced size in the first direction x as compared with the metal plate material 20. Unlike the present embodiment, a heat dissipation member with a plurality of standing pieces may be made, for example, by preparing a metal plate material with a plurality of V-shaped cutting lines and raising the portions surrounded by such cutting lines. In such a case, the heat dissipation member has the same (or approximately the same) size and shape as the metal plate material as viewed in the thickness direction, and therefore has actually not been reduced in size at all. As compared with such a heat dissipation member having a plurality of simple raised pieces, the heat dissipation member 2 of the present embodiment has a more complex three-dimensional shape. Such a complex shape can significantly increase the contact area with the flowing cooling medium Cm, which is desirable for increasing the heat dissipation efficiency.

Because the first protrusions 21 have the first standing portions 213, the second standing portions 214 and the first end portions 215, the first protrusions 21 have hollow portions as viewed in the second direction y. Thus, the heat dissipation member 2, which has the first protrusions 21 arranged in a matrix, facilitates the flow of the cooling medium Cm along the second direction y. Therefore, the electric power conversion unit B1 can achieve smooth flow of the cooling medium Cm in the second direction y.

The heat dissipation member 2 of the present embodiment includes a plurality of second protrusions 22 in addition to the plurality of first protrusions 21. The second protrusions 22 further protrude in the thickness direction z from the first end portions 215 of the first protrusions 21. Such a configuration can further increase the size of the heat dissipation member 2 in the thickness direction z to increase the contact area with the cooling medium Cm. This is suitable for increasing the heat dissipation efficiency.

In FIG. 28, (a) shows a bond plane P2 of the heat dissipation member 2. The bond plane P2 is a plane along the portions of the heat dissipation member 2 that face the reverse surface 302 when the heat dissipation member 2 is bonded to the reverse surface 302 of the support substrate 3. In the present embodiment, the bond plane P2 is a plane along the first base portions 211 and the second base portions 212 of the first protrusions 21.

In the present embodiment, the heat dissipation member 2 has a plurality of first protrusions 21 arranged in a matrix and is smaller than the metal plate material 20 in size in the first direction x. Therefore, three-dimensional bending deformation or torsional deformation of the heat dissipation member 2 is easier as compared with, for example, the metal plate material 20. For example, (b) in the figure shows the bending deformation in which the central part in the first direction x of the bond plane P2 is raised in the thickness direction z, and (c) in the figure shows the bending deformation in which the central part in the second direction y of the bond plane P2 is raised in the thickness direction z. Further, (d) in the figure shows the torsional deformation in which opposite ends in the first direction x of the bond plane P2 are turned in different directions. The heat dissipation member 2 has sufficient flexibility or elasticity to follow the bending deformation or torsional deformation shown in (b) to (d).

Even if deformations corresponding to those shown in (b) to (d) in FIG. 28 occur to the reverse surface 302 of the support substrate 3 due to manufacturing errors during the manufacturing process or thermal deformation during use, it is possible to properly fix the heat dissipation member 2 to the reverse surface 302 of the support substrate 3 by making the heat dissipation member 2 follow such deformations. In particular, formation of unintended gaps between the heat dissipation member 2 and the reverse surface 302 can be prevented also when bonding the first base portions 211 and the second base portion 212 to the reverse surface 302 by laser welding or the like causes such deformations as shown in (b) to (d).

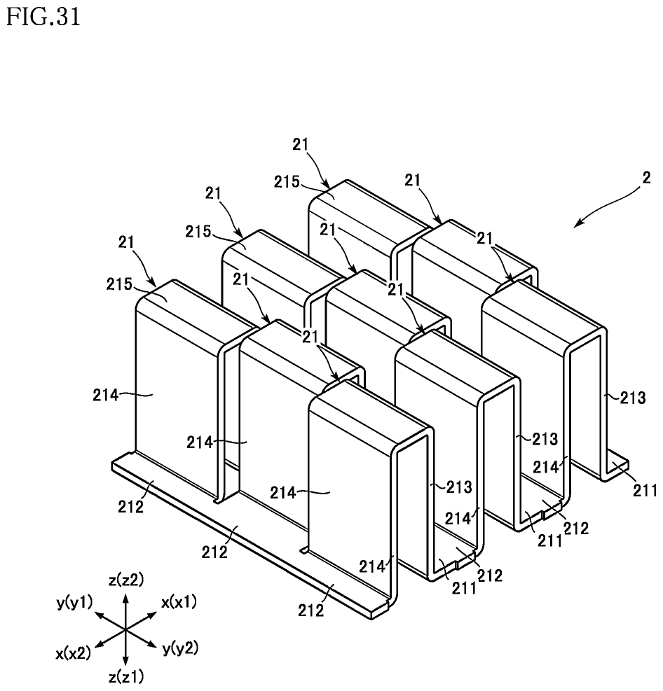

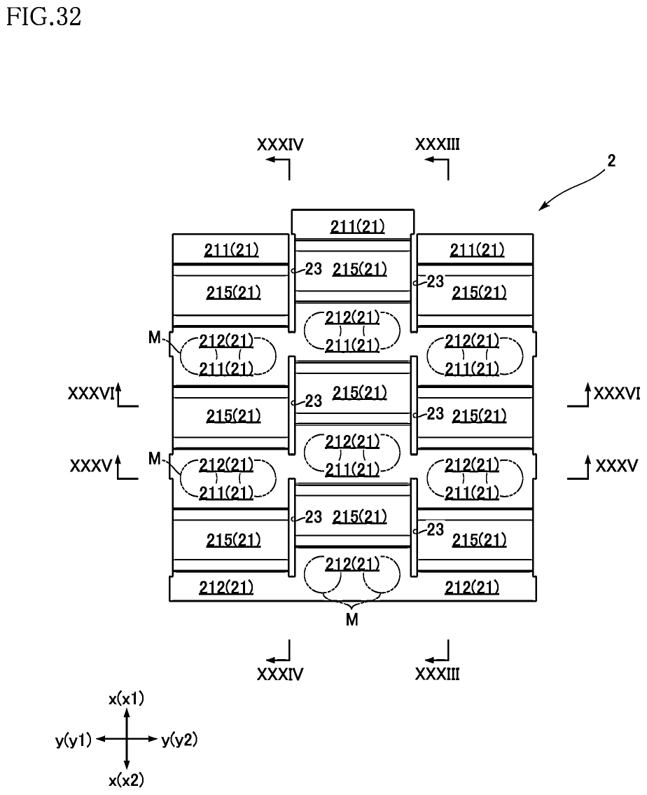

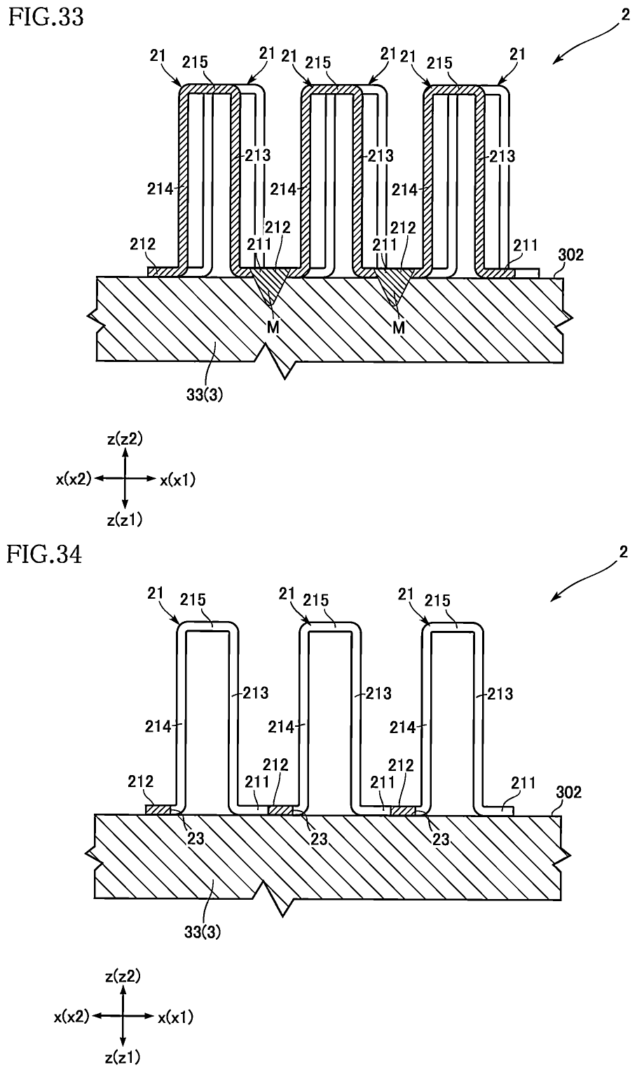

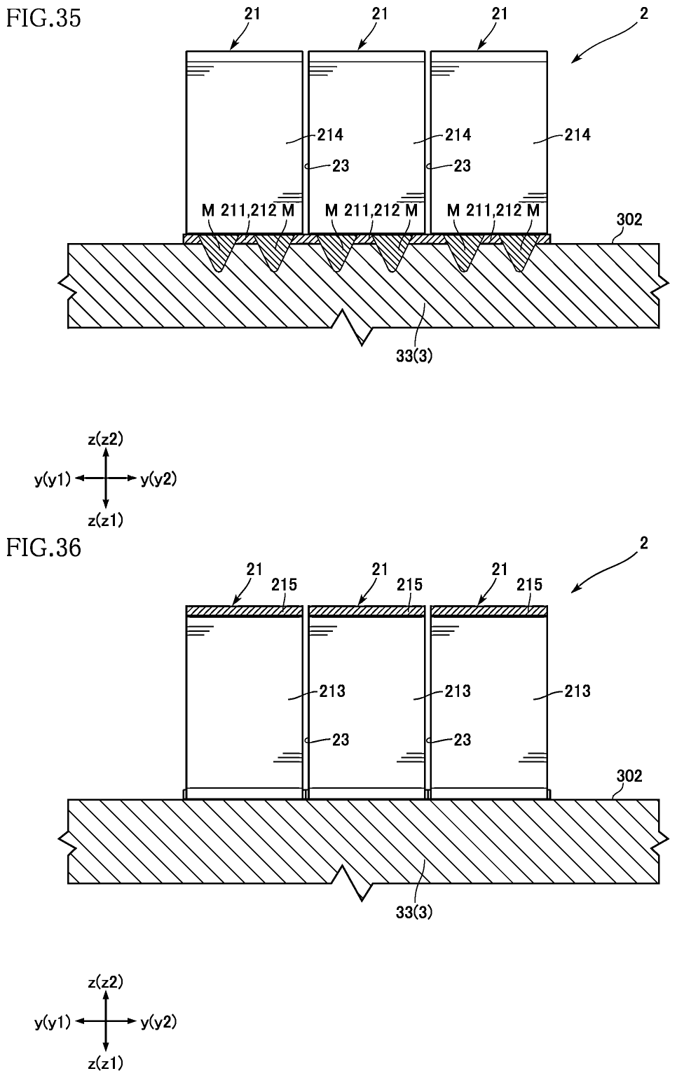

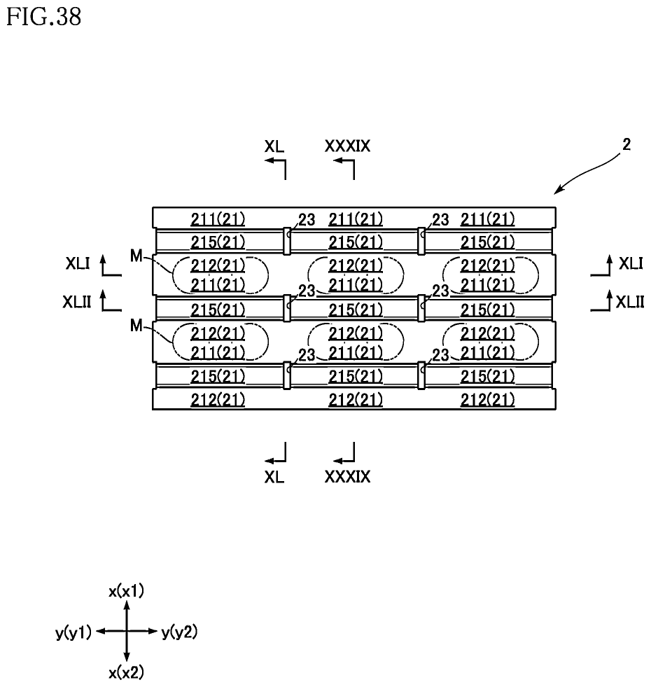

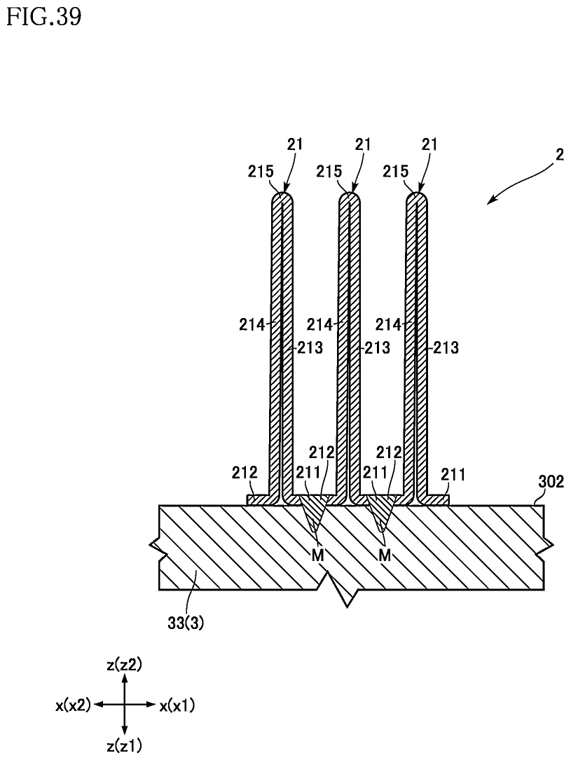

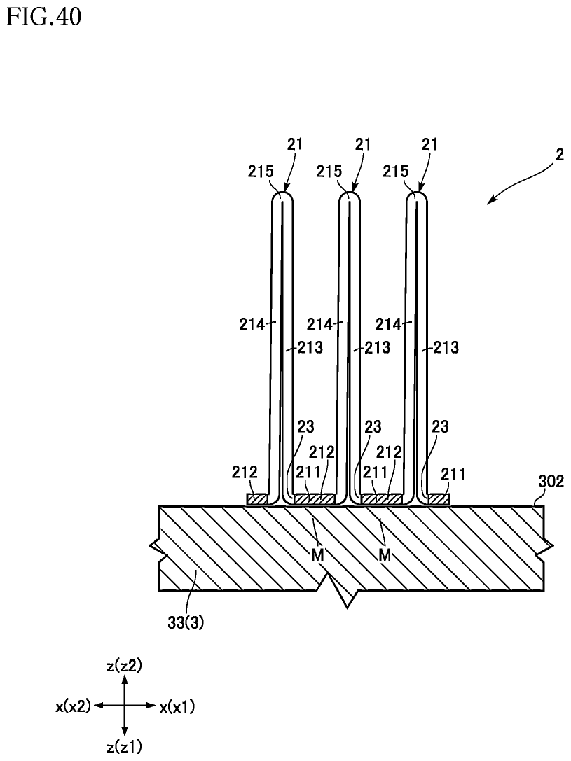

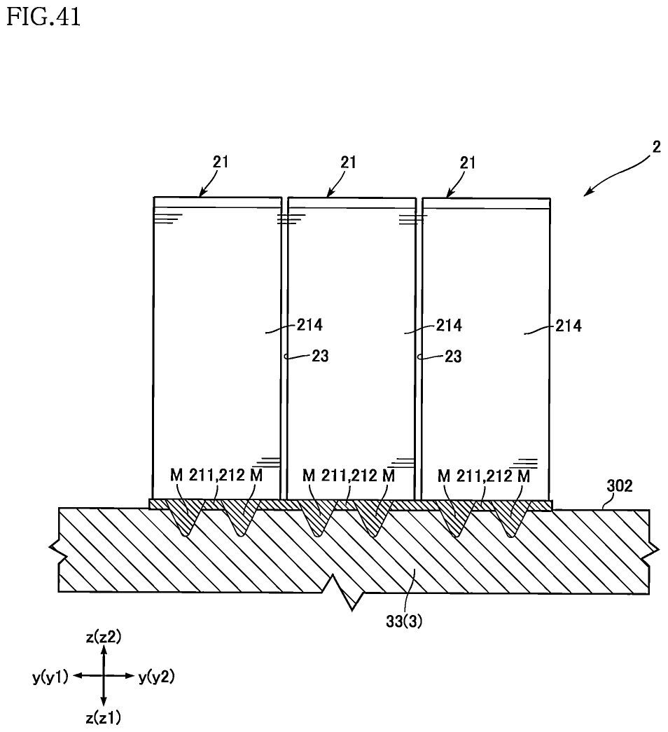

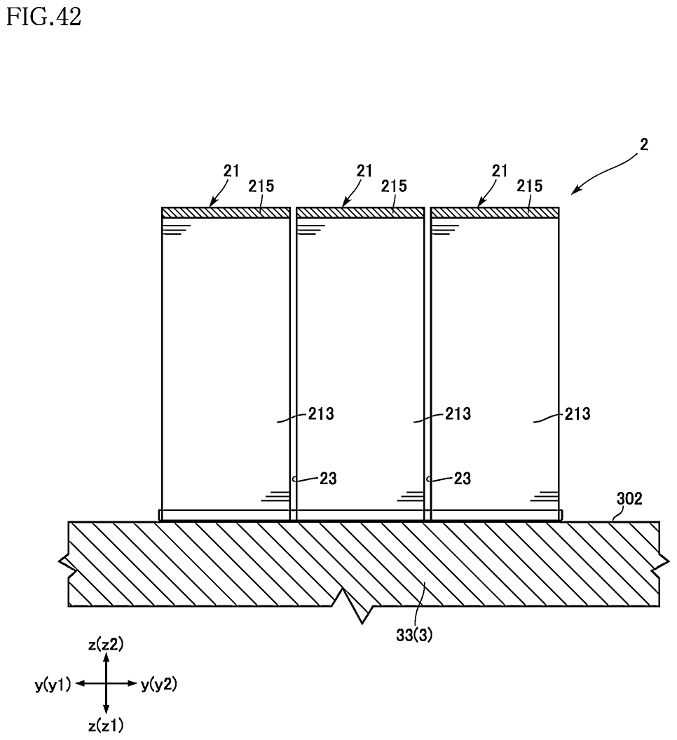

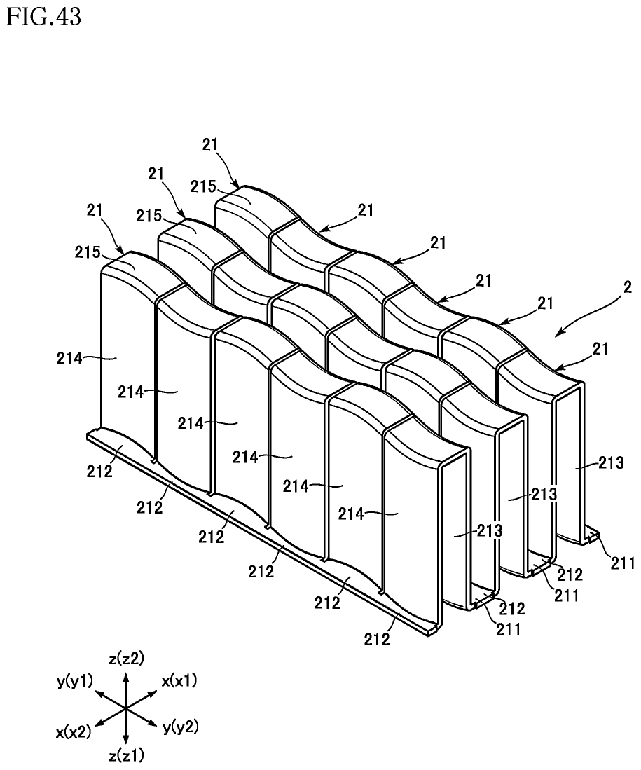

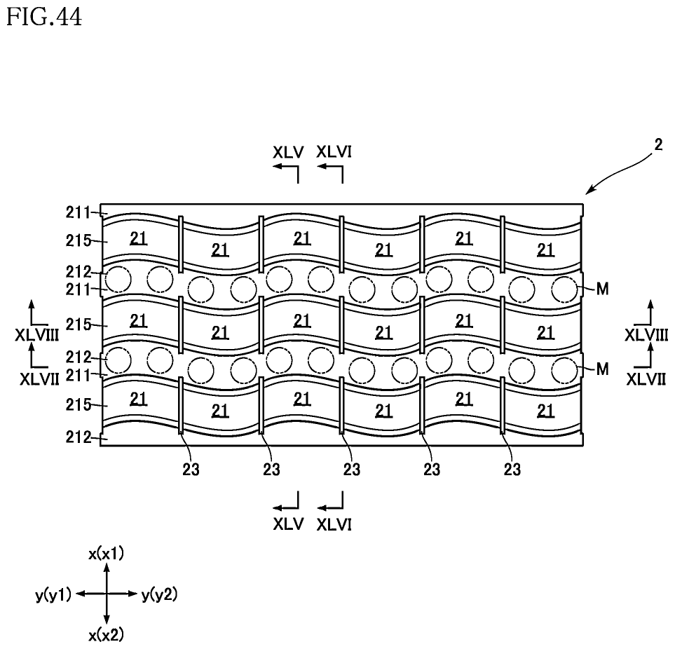

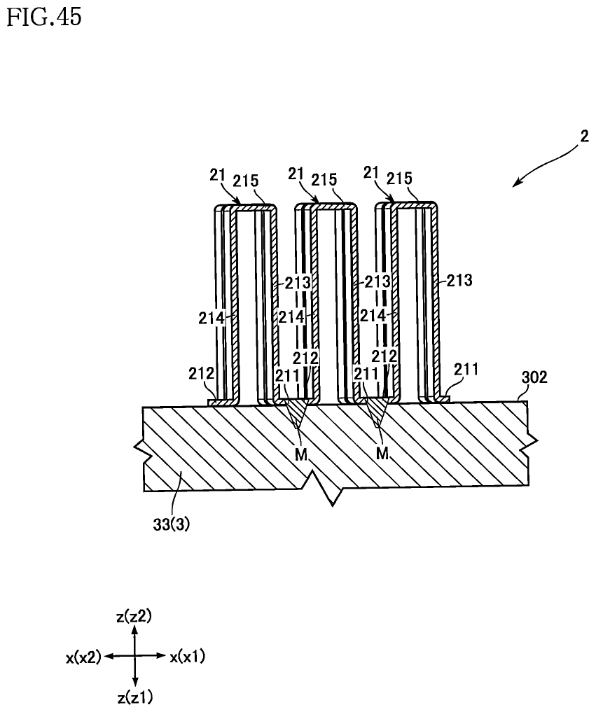

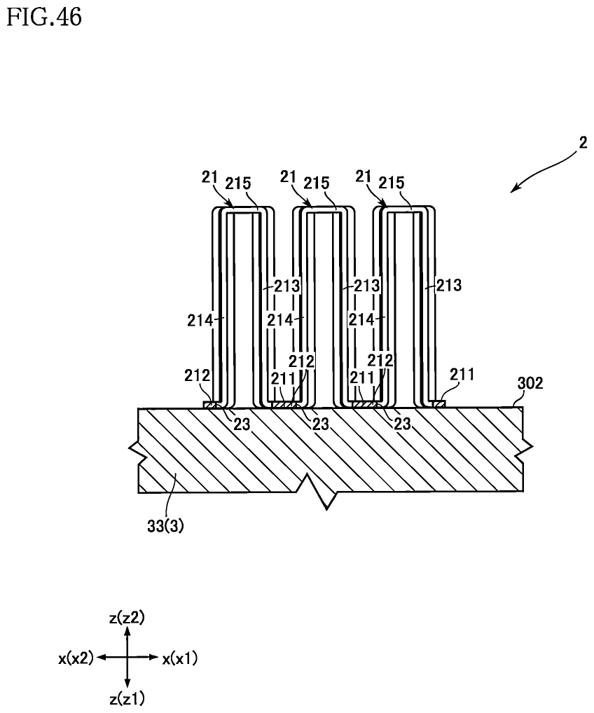

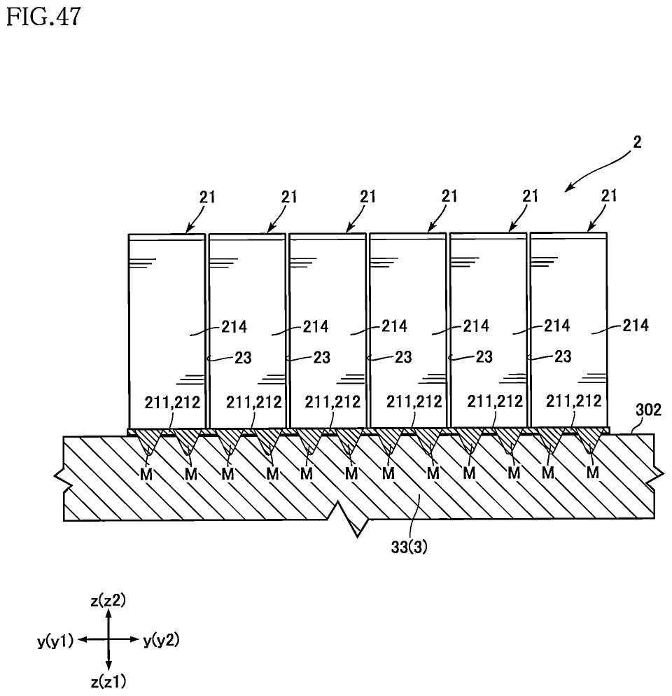

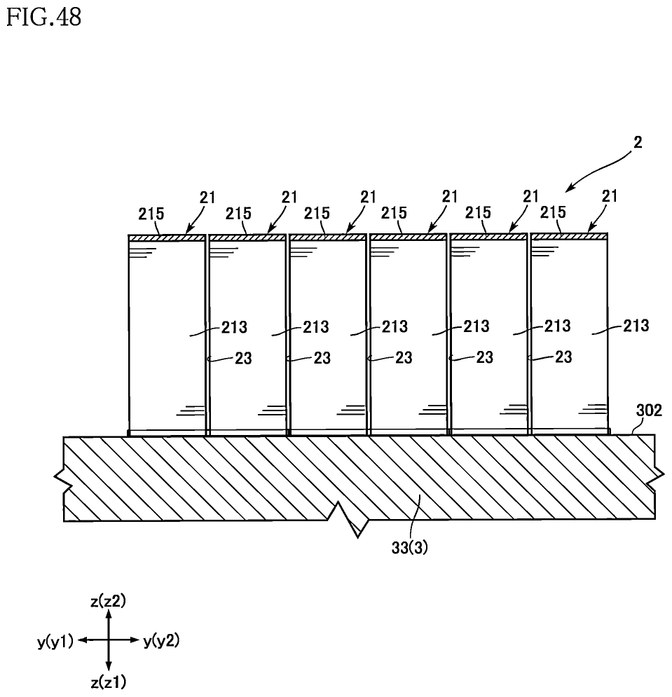

FIGS. 31 to 48 show other embodiments of the present disclosure. In these figures, the elements that are identical or similar to those of the above embodiment are denoted by the same reference signs as those of the above embodiment. Various parts of embodiments may be selectively used in any appropriate combination as long as it is technically compatible.

### SECOND EMBODIMENT

FIGS. 31 to 36 show a heat dissipation member of a semiconductor device according to a second embodiment of the present disclosure. The heat dissipation member 2 of the present embodiment includes a plurality of first protrusions 21, but does not include second protrusions 22.

In the present embodiment, the first protrusions 21 are arranged along the first direction x and the second direction y. The first base portion 211 of one of two first protrusions 21 adjacent to each other in the first direction x is connected to the second base portion 212 of the other one of the first protrusions, forming an integral portion. As for the first protrusions 21 adjacent to each other in the second direction y, their first base portions 211 are connected to each other, and their second base portions 212 are connected to each other. Thus, the first base portions 221 arranged along the second direction y and the second base portions 222 arranged along the second direction y of the first protrusions 21 respectively form strip-shaped portions extending along the second direction y as a whole as viewed in the thickness direction z.

The first standing portions 213 of the first protrusions 21 adjacent to each other in the second direction y are not connected to each other, the second standing portions 214 of the first protrusions 21 adjacent to each other in the second direction y are not connected to each other, and the first end portions 215 of the first protrusions 21 adjacent to each other in the second direction y are not connected to each other. In the present embodiment, the heat dissipation member 2 is formed with a plurality of slits 23. Each slit 23 has a thin elongated shape extending in the first direction x as viewed in the thickness direction z and located between two first protrusions 21 adjacent to each other in the second direction y.

In the present embodiment, the first protrusions 21 adjacent to each other in the second direction y are arranged offset from each other in the second direction y. That is, the plurality of first protrusions 21 arranged along the second direction y are staggered as viewed in the thickness direction z.

According to the present embodiment again, the heat from the first semiconductor elements 10A and the second semiconductor elements 10B can be quickly dissipated. In the present embodiment, the plurality of first protrusions 21 arranged along the second direction y are staggered as viewed in the thickness direction z. Therefore, the electric power conversion unit that uses the heat dissipation member 2 of the present embodiment achieves the meandering flow of the cooling medium Cm. Thus, the flow path of the cooling medium Cm can be extended, and the heat dissipation efficiency can be improved.

As understood from the present embodiment, the heat dissipation member 2 of the present disclosure is not limited to the configuration that includes both the first protrusions 21 and the second protrusions 22, and may be configured to have the first protrusions 21 and not to have the second protrusions 22.

### THIRD EMBODIMENT

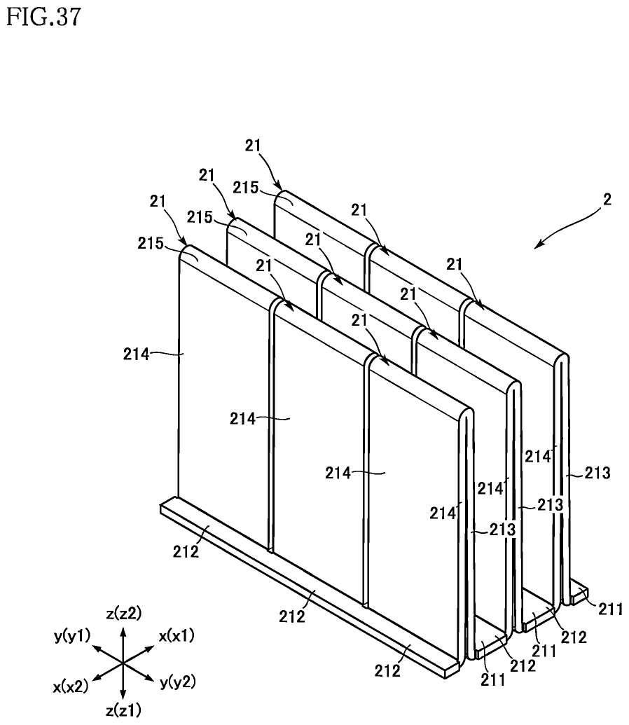

FIGS. 37 to 42 show a heat dissipation member of a semiconductor device according to a third embodiment of the present disclosure. The heat dissipation member 2 of the present embodiment includes a plurality of first protrusions 21.

In the present embodiment, the distance between the first standing portion 213 and the second standing portion 214 of each first protrusion 21 is smaller than that in the above embodiments. For example, the distance between the first standing portion 213 and the second standing portion 214 is smaller than the thickness of each of the first standing portion 213 standing 214 and the second portion and significantly smaller than the distance between the first protrusions 21 adjacent to each other in the first direction X.

The first end portion 215 of the present embodiment has a folded shape. That is, because the distance between the first standing portion 213 and the second standing portion 214 is significantly small, the dimension of the first end portion 215 in the first direction x is significantly smaller than that in the above embodiments.

In the present embodiment again, slits 23 are formed between the first protrusions 21 adjacent to each other in the second direction y.

According to the present embodiment again, the heat from the first semiconductor 10A and elements the second semiconductor elements 10B can be quickly dissipated. As understood from the present embodiment, the first protrusion 21 is not limited to the configuration in which the first standing portion 213, the second standing portion 214 and the first end portion 215 form a U-shape as viewed in the second direction y, and may have a flat shape in which the first standing portion 213 and the second standing portion 214 are very close. With such a configuration again, the cooling medium Cm flows through the space between adjacent first protrusions 21, and the heat dissipation efficiency can be improved. The shape of the first end portion 215 is not limited, and may have a curved surface bulging toward the z2 side in the thickness direction z, instead of a flat-plate shape or a folded shape.

### FOURTH EMBODIMENT

FIGS. 43 to 48 show a heat dissipation member of a semiconductor device according to a fourth embodiment of the present disclosure. The heat dissipation member 2 of the present embodiment includes a plurality of first protrusions 21.

In the present embodiment, the first end portion 215 of the first protrusion 21 is curved as viewed in the thickness direction z. Also, the first standing portion 213 and the second standing portion 214 have curved surfaces.

Specifically, the first end portions 215 of some first protrusions 21 are each curved such that its central part in the second direction y is offset toward the x1 side in the first direction x from its opposite ends in the second direction y. In these first protrusions 21, each of the first standing portion 213 and the second standing portion 214 has a curved surface such that its central part in the second direction y is offset toward the x1 side in the first direction x from its opposite ends in the second direction y as viewed in the thickness direction z.

The first end portions 215 of other first protrusion 21 are each curved such that its central part in the second direction y is offset toward the x2 side in the first direction x from its opposite ends in the second direction y. In these first protrusions 21, each of the first standing portion 213 and the second standing portion 214 has a curved surface such that its central part in the second direction y is offset toward the x2 side in the first direction x from its opposite ends in the second direction y as viewed in the thickness direction z.

In the present embodiment, the above-described two types of first protrusions 21 are alternately arranged in the second direction y. As a result, the first end portions 215 of the first protrusions 21 aligned in the second direction y present a strip-like shape that meanders in the second direction y as viewed in the thickness direction z. The first protrusions 21 aligned in the first direction x are curved toward the same side.

In the present embodiment again, the slits 23 are formed between the first protrusions 21 adjacent to each other in the second direction y.

According to the present embodiment again, the heat from the first semiconductor elements 10A and the second semiconductor elements 10B can be quickly dissipated. Further, according to the present embodiment, the first protrusions 21 aligned in the second direction y form a flow path meandering in the second direction y. Thus, the flow path of the cooling medium Cm can be extended, and the heat dissipation efficiency can be improved. Also, the space located between the first protrusions 21 in the first direction x form a flow path meandering in the second direction y. This also improves the heat dissipation efficiency.

As understood from the present embodiment, the first end portion 215 is not limited to a rectangular shape with sides parallel to the second direction y, but may have a curved shape with curved sides. Also, the first standing portion 213 and the second standing portion 214 are not limited to a flat-plate shape and may have a curved surface.

The semiconductor device, the electric power conversion unit, and the method for manufacturing the semiconductor device according to the present disclosure are not limited to the foregoing embodiments. Various modifications in design may be made freely in the specific configuration of the semiconductor device, the electric power conversion unit, and the method for manufacturing the semiconductor device according to the present disclosure. The present disclosure includes the embodiments described in the following clauses.

### Clause 1.

A semiconductor device comprising:
a semiconductor element;
a support substrate supporting the semiconductor element; and
a sealing resin covering the semiconductor element and a part of the support substrate, wherein
the support substrate includes an obverse surface facing a first side and a reverse surface facing a second side in a thickness direction, the reverse surface being exposed from the sealing resin,
the semiconductor element is mounted on the obverse surface,
the semiconductor device further includes a heat dissipation member disposed on the reverse surface,
the heat dissipation member includes a plurality of first protruding elements each including a first base portion, a second base portion, a first standing portion, a second standing portion, and a first end portion,
the first base portion and the second base portion are spaced apart from each other in a first direction orthogonal to the thickness direction and each bonded to the reverse surface,
the first end portion is located between the first base portion and the second base portion in the first direction and located on the second side in the thickness direction from the first base portion and the second base portion,
the first standing portion is connected to the first base portion and the first end portion,
the second standing portion is connected to the second base portion and the first end portion, and
the plurality of first protruding elements are arranged in a matrix along a plane containing the first direction and a second direction that is orthogonal to the thickness direction and the first direction.

### Clause 2.

The semiconductor device according to clause 1, wherein the first standing portions of two said first protruding elements adjacent to each other in the second direction are spaced apart from each other.

### Clause 3.

The semiconductor device according to clause 2, wherein the second standing portions of two said first protruding elements adjacent to each other in the second direction are spaced apart from each other.

### Clause 4.

The semiconductor device according to clause 3, wherein the first base portion of one of two said first protruding elements adjacent to each other in the first direction is connected to the second base portion of the other one of two said first protruding elements.

### Clause 5.

The semiconductor device according to clause 4, wherein the first base portions of two said first protruding elements adjacent to each other in the second direction are spaced apart from each other, and
the second base portions of two said first protruding elements adjacent to each other in the second direction are spaced apart from each other.

### Clause 6.

The semiconductor device according to clause 5, wherein the heat dissipation member includes a plurality of second protruding elements each including a third base portion, a fourth base portion, a third standing portion, a fourth standing portion, and a second end portion,
the third base portion is connected to the first end portions of two said first protruding elements adjacent to each other in the second direction,
the fourth base portion is connected to the first end portions of other two first protruding elements adjacent to each other in the second direction,
the second end portion is located between the third base portion and the fourth base portion in the first direction and located on the second side in the thickness direction from the third base portion and the fourth base portion,
the third standing portion is connected to the third base portion and the second end portion, and
the fourth standing portion is connected to the fourth base portion and the second end portion.

### Clause 7.

The semiconductor device according to clause 6, wherein a size of the second protruding element in the thickness direction is greater than a distance between the third standing portion and the fourth standing portion in the first direction.

### Clause 8.

The semiconductor device according to any one of clauses 1 to 7, wherein a size of the first protruding element in the thickness direction is greater than a distance between the first standing portion and the second standing portion in the first direction.

### Clause 9.

The semiconductor device according to clause 4, wherein the first base portions of two said first protruding elements adjacent to each other in the second direction are connected to each other, and
the second base portions of two said first protruding elements adjacent to each other in the second direction are connected to each other.

### Clause 10.

The semiconductor device according to clause 9, wherein the first protruding elements adjacent to each other in the second direction are arranged offset from each other in the second direction.

### Clause 11.

The semiconductor device according to clause 9, wherein the first end portion is curved as viewed in the thickness direction, and
the first standing portion and the second standing portion have curved surfaces.

### Clause 12.

The semiconductor device according to any one of clauses 9 to 11, wherein the heat dissipation member includes a slit located between the first standing portions, between the second standing portions, and between the first end portions of two said first protruding elements adjacent to each other in the second direction.

### Clause 13.

The semiconductor device according to any one of clauses 1 to 12, wherein the first end portion has a shape of a flat plate.

### Clause 14.

The semiconductor device according to any one of clauses 1 to 12, wherein the first end portion has a folded shape.

### Clause 15.

The semiconductor device according to any one of clauses 1 to 14, wherein the first base portion and the second base portion are bonded to the reverse surface by welding.

### Clause 16.

An electric power conversion unit comprising:
the semiconductor device as set forth in any one of clauses 1 to 15; and
a cooling device disposed on the second side of the semiconductor device in the thickness direction,
wherein the cooling device includes a housing that houses the heat dissipation member and that is configured to flow cooling medium.

### Clause 17.

The electric power conversion unit according to clause 16, wherein the cooling medium flows in the second direction in the housing.

### Clause 18.

A method for manufacturing a semiconductor device, the method comprising the steps of:
forming a heat dissipation member using a metal plate material; and
disposing the heat dissipation member on a reverse surface of a support substrate,
wherein the step of forming the heat dissipation member includes:

forming a plurality of cutting lines along a first direction that is orthogonal to a thickness direction of the metal plate material; and
forming a plurality of first protruding elements by deforming portions of the metal plate material located between the cutting lines adjacent to each other in a second direction orthogonal to the thickness direction and the first direction into shapes protruding in the thickness direction.

### Clause 19.

The method for manufacturing a semiconductor device according to clause 18, wherein a size of the heat dissipation member in the first direction is smaller than a size of the metal plate material in the first direction.

### Clause 20.

The method for manufacturing a semiconductor device according to clause 18 or 19, wherein the step of disposing the heat dissipation member on the reverse surface of the support substrate includes bonding the heat dissipation member to the reverse surface by laser welding.

### REFERENCE NUMERALS

A1: Semiconductor device B1: Electric power conversion unit
2: Heat dissipation member 3: Support substrate
5: First conductive member 6: Second conductive member
8: Sealing resin 9: Cooling device
10A: First semiconductor element
10B: Second semiconductor element
11: First obverse-surface electrode
12: Second obverse-surface electrode
13: Third obverse-surface electrode
15: Reverse-surface electrode
17: Thermistor 19A: First conductive bonding material
19B: Second conductive bonding material 20: Metal plate material
21: First protrusion 22: Second protrusion
23: Slit 31: Insulating layer
32: First metal layer 32A: First conductive portion
32B: Second conductive portion 33: Reverse-surface metal layer
35: First metal portion 36: Second metal portion
41: First terminal 42: Second terminal
43: Third terminal 44: Fourth terminal
45: Control terminal
46A, 46B, 46C, 46D, 46E: First control terminal
47A, 47B, 47C, 47D: Second control terminal
48: Control terminal support 48A: First support portion
48B: Second support portion 49: Bonding material
52: First bond portion 51: Main portion
59: Conductive bonding material 53: Second bond portion
61: Third bond portion 64: First path portion
65: Second path portion 66: Third path portion
67: Fourth path portion 69: Conductive bonding material
71, 72, 73, 74: Wire 81: Resin obverse surface
82: Resin reverse surface 86: Resin void portion
89: Groove 91: Housing
92: Supply section 93: Discharge section
101: Element obverse surface 102: Element reverse surface
121: Gate finger 201: Cutting line
211: First base portion 212: Second base portion
213: First standing portion 214: Second standing portion
215: First end portion 221: Third base portion
222: Fourth base portion 223: Third standing portion
224: Fourth standing portion 225: Second end portion
301A: First obverse surface 301B: Second obverse surface
302: Reverse surface 451: Holder
452: Metal pin 459: Conductive bonding material
481: Insulating layer 482: First metal layer
482A: First portion 482B: Second portion
482C: Third portion 482D: Fourth portion
482E: Fifth portion 482F: Sixth portion
483: Second metal layer 514: First opening
602: First stepped portion 603: Second stepped portion
611: Flat section 612: First inclined section
641: First strip portion 643: First extension portion
649: Recess 651: Second strip portion
653: Second extension portion 659, 669: Recess
831, 832: Resin side surface 832a: Recess
833: Resin side surface 834: Resin side surface
851: First projection 851a: Projection end surface
851b: Recess 851c: Inner wall surface
852: Second projection 919: Sealing material
Cm: Cooling medium M: Weld portion
x: First direction y: Second direction
z: Thickness direction

1. A semiconductor device comprising:
a semiconductor element;
a support substrate supporting the semiconductor element; and
a sealing resin covering the semiconductor element and a part of the support substrate, wherein
the support substrate includes an obverse surface facing a first side and a reverse surface facing a second side in a thickness direction, the reverse surface being exposed from the sealing resin,
the semiconductor element is mounted on the obverse surface,
the semiconductor device further includes a heat dissipation member disposed on the reverse surface,
the heat dissipation member includes a plurality of first protruding elements each including a first base portion, a second base portion, a first standing portion, a second standing portion, and a first end portion,
the first base portion and the second base portion are spaced apart from each other in a first direction orthogonal to the thickness direction and each bonded to the reverse surface,
the first end portion is located between the first base portion and the second base portion in the first direction and located on the second side in the thickness direction from the first base portion and the second base portion,
the first standing portion is connected to the first base portion and the first end portion,
the second standing portion is connected to the second base portion and the first end portion, and
the plurality of first protruding elements are arranged in a matrix along a plane containing the first direction and a second direction that is orthogonal to the thickness direction and the first direction.

2. The semiconductor device according to claim 1, wherein the first standing portions of two said first protruding elements adjacent to each other in the second direction are spaced apart from each other.

3. The semiconductor device according to claim 2, wherein the second standing portions of two said first protruding elements adjacent to each other in the second direction are spaced apart from each other.

4. The semiconductor device according to claim 3, wherein the first base portion of one of two said first protruding elements adjacent to each other in the first direction is connected to the second base portion of the other one of two said first protruding elements.

5. The semiconductor device according to claim 4, wherein the first base portions of two said first protruding elements adjacent to each other in the second direction are spaced apart from each other, and
the second base portions of two said first protruding elements adjacent to each other in the second direction are spaced apart from each other.

6. The semiconductor device according to claim 5, wherein the heat dissipation member includes a plurality of second protruding elements each including a third base portion, a fourth base portion, a third standing portion, a fourth standing portion, and a second end portion,
the third base portion is connected to the first end portions of two said first protruding elements adjacent to each other in the second direction,
the fourth base portion is connected to the first end portions of other two first protruding elements adjacent to each other in the second direction,
the second end portion is located between the third base portion and the fourth base portion in the first direction and located on the second side in the thickness direction from the third base portion and the fourth base portion,
the third standing portion is connected to the third base portion and the second end portion, and
the fourth standing portion is connected to the fourth base portion and the second end portion.

7. The semiconductor device according to claim 6, wherein a size of the second protruding element in the thickness direction is greater than a distance between the third standing portion and the fourth standing portion in the first direction.

8. The semiconductor device according to claim 1, wherein a size of the first protruding element in the thickness direction is greater than a distance between the first standing portion and the second standing portion in the first direction.

9. The semiconductor device according to claim 4, wherein the first base portions of two said first protruding elements adjacent to each other in the second direction are connected to each other, and
the second base portions of two said first protruding elements adjacent to each other in the second direction are connected to each other.

10. The semiconductor device according to claim 9, wherein the first protruding elements adjacent to each other in the second direction are arranged offset from each other in the second direction.

11. The semiconductor device according to claim 9, wherein the first end portion is curved as viewed in the thickness direction, and
the first standing portion and the second standing portion have curved surfaces.

12. The semiconductor device according to claim 9, wherein the heat dissipation member includes a slit located between the first standing portions, between the second standing portions, and between the first end portions of two said first protruding elements adjacent to each other in the second direction.

13. The semiconductor device according to claim 1, wherein the first end portion has a shape of a flat plate.

14. The semiconductor device according to claim 1, wherein the first end portion has a folded shape.

15. The semiconductor device according to claim 1, wherein the first base portion and the second base portion are bonded to the reverse surface by welding.

16. An electric power conversion unit comprising:
the semiconductor device as set forth in claim 1; and
a cooling device disposed on the second side of the semiconductor device in the thickness direction,
wherein the cooling device includes a housing that houses the heat dissipation member and that is configured to flow cooling medium.

17. The electric power conversion unit according to claim 16, wherein the cooling medium flows in the second direction in the housing.

18. A method for manufacturing a semiconductor device, the method comprising the steps of:
forming a heat dissipation member using a metal plate material; and
disposing the heat dissipation member on a reverse surface of a support substrate,
wherein the step of forming the heat dissipation member includes:
forming a plurality of cutting lines along a first direction that is orthogonal to a thickness direction of the metal plate material; and
forming a plurality of first protruding elements by deforming portions of the metal plate material located between the cutting lines adjacent to each other in a second direction orthogonal to the thickness direction and the first direction into shapes protruding in the thickness direction.

19. The method for manufacturing a semiconductor device according to claim 18, wherein a size of the heat dissipation member in the first direction is smaller than a size of the metal plate material in the first direction.

20. The method for manufacturing a semiconductor device according to claim 18, wherein the step of disposing the heat dissipation member on the reverse surface of the support substrate includes bonding the heat dissipation member to the reverse surface by laser welding.
